(19) United States
(12) Patent Application Publication
(10) Pub. No.: US 2023/0114399 A1
(43) Pub. Date: Apr. 13, 2023

(54) COMPONENT MOUNTING SYSTEM AND METHOD FOR HANDLING CARRIER TAPE ROLL BODY

(71) Applicant: Panasonic Intellectual Property Management Co., Ltd., Osaka (JP)

(72) Inventor: YASUYUKI ISHITANI, Yamanashi (JP)

(21) Appl. No.: 17/904,850

(22) PCT Filed: Feb. 2, 2021
(86) PCT No.: PCT/JP2021/003635

§ 371 Date: Aug. 23, 2022

(30) Foreign Application Priority Data
Mar. 25, 2020 (JP) 2020-053541

(51) Int. Cl. B65H 67/02; B65H 67/04

(52) U.S. Cl. CPC B65H 67/02; B65H 67/0428; B65H 2701/11332

(57) ABSTRACT

A component mounting system for handling a carrier tape roll body to be extracted from a reel and housed in a case, the carrier tape roll body including a roll body formed by winding a carrier tape in a roll shape and a memory that is provided on the carrier tape and enables reading and writing by wireless communication, includes: an identification information generator that generates identification information to be used to distinguish a component sealed in the carrier tape of the carrier tape roll body housed in the case from a component sealed in another carrier tape; and a writing unit that writes the identification information generated by the identification information generator into a memory.

### TECHNICAL FIELD

The present invention relates to a component mounting system that handles a carrier tape roll body including a carrier tape wound in a roll shape, and a method for handling the carrier tape roll.

### BACKGROUND ART

Conventionally, a tape feeder that supplies a component to a component extraction position by conveying a carrier tape housing the component has been known as a component supply unit in a component mounting device for mounting a component on a board. The carrier tape used in the tape feeder is wound around a reel as a holding body, and transport and storage of the carrier tape, setting with respect to the component supply unit, and the like are performed in the state of being wound around the reel. In this case, information on the component housed in the carrier tape (information such as component information which is various information related to the component and identification information used to distinguish the component sealed in the carrier tape from a component sealed in another carrier tape) is typically stored in an identifier, such as a barcode affixed to the reel, and read out as necessary by a handy scanner or the like.

Meanwhile, the tape feeder is required to be narrowed in dimension in the width direction in accordance with downsizing of the component mounting device, and a tape feeder having a thin width has been put to practical use. Meanwhile, the reel for housing the carrier tape is a standard product, and it is difficult to reduce a dimension of the reel in the width direction, and thus, there is proposed a device that enables supply of the carrier tape in a state of a roll body wound in a roll shape to a component supply unit (see PTL 1).

### CITATION LIST

### Patent Literature

PTL 1: Unexamined Japanese Patent Publication No. H5-21990

### SUMMARY OF THE INVENTION

A component mounting system according to one aspect of the present invention is a component mounting system for handling a carrier tape roll body to be extracted from a holding body holding the carrier tape roll body and housed in a case, the carrier tape roll body including a roll body formed by winding a carrier tape in a roll shape, the carrier tape sealing components respectively in a plurality of pockets formed at regular intervals, and a memory that is provided on the carrier tape wound in the roll shape and allows reading and writing by wireless communication, and includes: an identification information generator that generates identification information, used to distinguish the components sealed in the carrier tape of the carrier tape roll body housed in the case from components sealed in another carrier tape; and an identification information writing unit that writes the identification information generated by the identification information generator into the memory.

A method for handling a carrier tape roll body according to one aspect of the present invention is a method for handling a carrier tape roll body by which a carrier tape roll body is handled to be extracted from a holding body holding the carrier tape roll body and housed in a case, the carrier tape roll body including a roll body formed by winding a carrier tape in a roll shape, the carrier tape sealing components respectively in a plurality of pockets formed at regular intervals, and a memory that is provided on the carrier tape wound in the roll shape and allows reading and writing by wireless communication, and includes: an identification information generation process of generating identification information to be used to distinguish the components sealed in the carrier tape of the carrier tape roll body housed in the case from components sealed in another carrier tape; and an identification information writing process of writing the identification information generated in the identification information generation process into the memory.

### BRIEF DESCRIPTION OF THE DRAWINGS

FIG. 1 is a schematic configuration diagram of a component mounting system according to an exemplary embodiment of the present invention.

FIG. 2 is a side view of the component mounting device included in the component mounting system according to the exemplary embodiment of the present invention.

FIG. 3A is a perspective view of an encased carrier tape roll body that is used in the component mounting device according to the exemplary embodiment of the present invention.

FIG. 3B is a perspective view of the encased carrier tape roll body that is used in the component mounting device according to the exemplary embodiment of the present invention.

FIG. 4A is a perspective view of a case of the encased carrier tape roll body according to the exemplary embodiment of the present invention.

FIG. 4B is a partially enlarged view of the case of the encased carrier tape roll body according to the exemplary embodiment of the present invention.

FIG. 5A is a perspective view of the encased carrier tape roll body according to the exemplary embodiment of the present invention.

FIG. 5B is a partially enlarged view of the encased carrier tape roll body according to the exemplary embodiment of the present invention.

FIG. 6A is a view illustrating a usage mode of the encased carrier tape roll body according to the exemplary embodiment of the present invention.

FIG. 6B is a view illustrating a usage mode of the encased carrier tape roll body according to the exemplary embodiment of the present invention.

FIG. 6C is a view illustrating a usage mode of the encased carrier tape roll body according to the exemplary embodiment of the present invention.

FIG. 7 is a view illustrating a configuration of a carrier tape roll body manufacturing device provided in the component mounting system according to the exemplary embodiment of the present invention.

FIG. 8A is a view illustrating a state where a carrier tape is drawn from a tape supply part of the carrier tape roll body manufacturing device according to the exemplary embodiment of the present invention.

FIG. 8B is an enlarged view of a part of the carrier tape drawn from the tape supply part of the carrier tape roll body manufacturing device according to the exemplary embodiment of the present invention.

FIG. 9A is a view illustrating a manufacturing procedure of the carrier tape roll body by the carrier tape roll body manufacturing device according to a mode of the exemplary embodiment of the present invention.

FIG. 9B is a view illustrating the manufacturing procedure of the carrier tape roll body by the carrier tape roll body manufacturing device according to the mode of the exemplary embodiment of the present invention.

FIG. 10A is a view illustrating the manufacturing procedure of the carrier tape roll body by the carrier tape roll body manufacturing device according to the exemplary embodiment of the present invention.

FIG. 10B is a view illustrating the manufacturing procedure of the carrier tape roll body by the carrier tape roll body manufacturing device according to the exemplary embodiment of the present invention.

FIG. 11A is a view illustrating the manufacturing procedure of the carrier tape roll body by the carrier tape roll body manufacturing device according to the exemplary embodiment of the present invention.

FIG. 11B is a view illustrating the manufacturing procedure of the carrier tape roll body by the carrier tape roll body manufacturing device according to the exemplary embodiment of the present invention.

FIG. 12A is a partially enlarged view of the carrier tape drawn from a tape supply reel provided in the carrier tape roll body manufacturing device according to the exemplary embodiment of the present invention.

FIG. 12B is a partially enlarged view of the carrier tape drawn from the tape supply reel provided in the carrier tape roll body manufacturing device according to the exemplary embodiment of the present invention.

FIG. 13A is a view illustrating the manufacturing procedure of the carrier tape roll body by the carrier tape roll body manufacturing device according to the exemplary embodiment of the present invention.

FIG. 13B is a view illustrating the manufacturing procedure of the carrier tape roll body by the carrier tape roll body manufacturing device according to the exemplary embodiment of the present invention.

FIG. 14 is a perspective view of a reel-equipped carrier tape roll body according to the exemplary embodiment of the present invention.

FIG. 15 is an exploded view of a reel of the reel-equipped carrier tape roll body that is used when a carrier tape roll body handling device according to the exemplary embodiment of the present invention manufactures the encased carrier tape roll body.

FIG. 16 is a perspective view of the carrier tape roll body handling device according to the exemplary embodiment of the present invention.

FIG. 17 is a side view of the carrier tape roll body handling device according to the exemplary embodiment of the present invention.

FIG. 18 is a front view of a main part of the carrier tape roll body handling device according to the exemplary embodiment of the present invention.

FIG. 19A is a view for describing an operation of disassembling the reel by the carrier tape roll body handling device according to the exemplary embodiment of the present invention.

FIG. 19B is a view for describing the operation of disassembling the reel by the carrier tape roll body handling device according to the exemplary embodiment of the present invention.

FIG. 19C is a view for describing the operation of disassembling the reel by the carrier tape roll body handling device according to the exemplary embodiment of the present invention.

FIG. 20 is a view illustrating a state immediately after the reel is disassembled by the carrier tape roll body handling device according to the exemplary embodiment of the present invention.

FIG. 21 is a perspective view of a storage warehouse according to the exemplary embodiment of the present invention.

FIG. 22 is a block diagram illustrating a control system of the component mounting system according to the exemplary embodiment of the present invention.

FIG. 23 is a flowchart illustrating a flow of work of manufacturing the carrier tape roll body by the carrier tape roll body manufacturing device according to the exemplary embodiment of the present invention.

FIG. 24 is a flowchart illustrating a flow of work of handling the carrier tape by the carrier tape roll body handling device according to the exemplary embodiment of the present invention.

FIG. 25 is a flowchart illustrating a flow of work of storing the encased carrier tape roll body in the storage warehouse according to the exemplary embodiment of the present invention.

FIG. 26 is a view illustrating an image of the operation of the encased carrier tape roll body according to the exemplary embodiment of the present invention.

### DESCRIPTION OF EMBODIMENT

Prior to describing an exemplary embodiment of the present invention, a problem of a conventional device will be briefly described.

In the case of the operation with a roll body of a carrier tape without a reel, a bar code or the like affixed to the reel is also lost, and thus, there is a problem that information on a component sealed in the carrier tape may become unknown.

Therefore, the present invention aims to solve the above problem and provide a component mounting system using a carrier tape roll body that has no holding body such as a reel (that is reel-less) and a method for handling the carrier tape roll body.

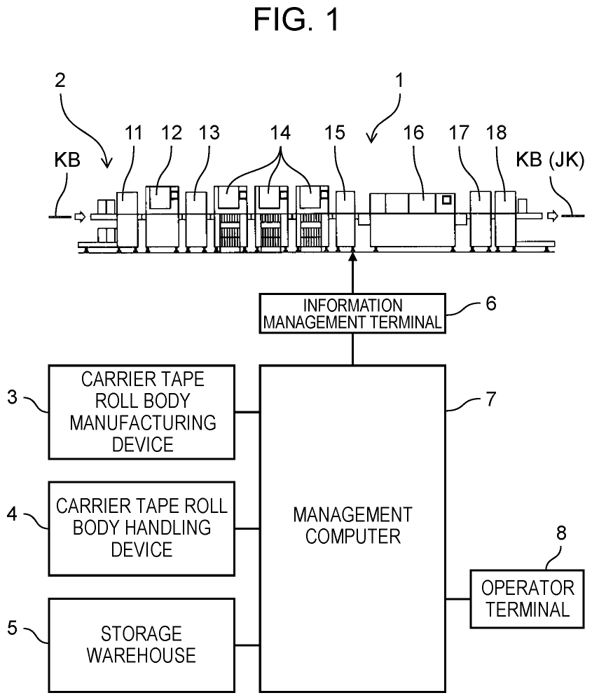

Hereinafter, the exemplary embodiment of the present invention will be described with reference to the drawings. FIG. 1 is a configuration diagram of component mounting system 1 using the carrier tape roll body according to the exemplary embodiment of the present invention. Component mounting system 1 includes carrier tape roll body manufacturing device 3, carrier tape roll body handling device 4, and storage warehouse 5 in addition to manufacturing line 2 for manufacturing mounting board JK in which components are mounted on board KB by performing work while receiving and transferring board KB among a plurality of devices connected in series.

In FIG. 1, manufacturing line 2 is connected to management computer 7 through information management terminal 6, and operations of devices constituting manufacturing line 2 can be managed by management computer 7. In addition, carrier tape roll body manufacturing device 3, carrier tape roll body handling device 4, and storage warehouse 5 are also connected to management computer 7 as illustrated in FIG. 1, and operations of carrier tape roll body manufacturing device 3, carrier tape roll body handling device 4, and storage warehouse 5 can be managed by management computer 7. As illustrated in FIG. 1, operator terminal 8 is connected to management computer 7, and an operator of component mounting system 1 can perform various operation inputs from operator terminal 8 to component mounting system 1.

First, manufacturing line 2 will be described. In FIG. 1, manufacturing line 2 includes board supply device 11, printing device 12, post-printing inspection device 13, a plurality of component mounting devices 14, post-mounting inspection device 15, reflow device 16, final inspection device 17, and board collection device 18.

Board supply device 11 sequentially supplies boards KB to printing device 12 on the downstream side. Printing device 12 carries in board KB supplied from board supply device 11, applies paste solder to an electrode formed on the surface of board KB, and carries out board KB to post-printing inspection device 13 on the downstream side. Post-printing inspection device 13 carries in board KB carried out from printing device 12, performs inspection by observing whether there is a place where the solder is applied in a defective state using a camera, and then, carries out board KB to component mounting device 14 on the downstream side.

Each of component mounting devices 14 mounts a component on board KB carried in from the upstream side and carries out the component to the downstream side. Component mounting device 14 located on the most downstream side carries out board KB to post-mounting inspection device 15 located on the downstream side. Component mounting device 14 will be described later.

Post-mounting inspection device 15 carries in board KB, carried out from component mounting device 14 located on the most downstream side, performs inspection by observing whether there is a place where the component is mounted in a defective state using a camera, and then, carries out board KB to reflow device 16 on the downstream side. Reflow device 16 carries in board KB carried out from post-mounting inspection device 15, and causes board KB to pass through a reflow furnace to melt and solidify the solder, thereby bonding the component to the electrode. Final inspection device 17 carries in board KB that has passed through reflow device 16, performs inspection by observing a bonding state of the component with respect to the electrode using a camera, and then, carries out board KB to board collection device 18 on the downstream side. Board collection device 18 receives and collects board KB carried out from final inspection device 17.

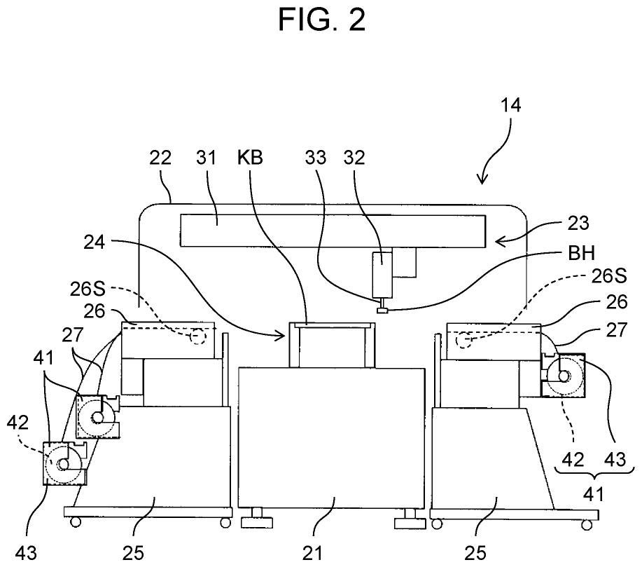

Next, component mounting device 14 will be described with reference to FIG. 2. In FIG. 2, base cover 22 is provided on base 21 of component mounting device 14, and board conveyance path 24 that conveys board KB in the horizontal direction is provided in work space 23 between base 21 and base cover 22.

Feeder carriages 25 are connected to positions on both sides of board conveyance path 24 on base 21. A plurality of component supply units 26 is attached to each of feeder carriages 25. Here, component supply unit 26 is a tape feeder, and conveys carrier tape 27 by sprocket 26S to supply components BH one by one to a predetermined component supply positions.

In FIG. 2, mounting head 32 that is moved in the horizontal direction by head moving mechanism 31 is provided in work space 23. Mounting head 32 is provided with component suction nozzle 33 extending downward. Component BH supplied by component supply unit 26 can be sucked to a lower end of component suction nozzle 33.

When board conveyance path 24 carries in board KB from the upstream side and positions board KB, each of component mounting devices 14 causes mounting head 32 to repeatedly perform a mounting turn while causing component supply unit 26 to supply component BH. In one mounting turn, mounting head 32 performs an operation of sucking and picking up component BH supplied by component supply unit 26 and an operation of mounting component BH at a component mounting position defined on board KB in this order. When all of components BH to be mounted on board KB are mounted by repeatedly performing the mounting turns on mounting head 32, board conveyance path 24 is activated to carry out board KB to the downstream side.

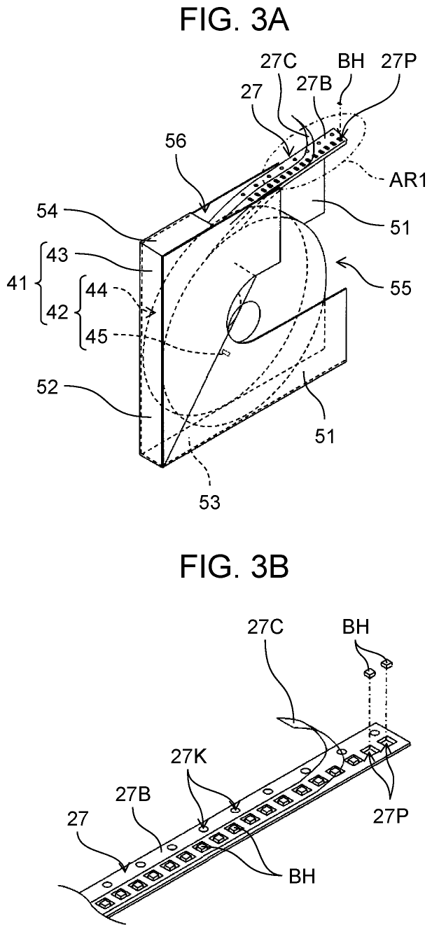

In the present exemplary embodiment, carrier tape 27 to be used by component mounting device 14 for supplying component BH is fed out and supplied from encased carrier tape roll body 41 illustrated in FIG. 3A. Encased carrier tape roll body 41 is configured such that carrier tape roll body 42 is housed in case 43, and carrier tape roll body 42 includes roll body 44 formed by winding carrier tape 27 in a roll shape and memory 45 provided at an end part of carrier tape 27, wound in the roll shape, on the center side of roll body 44.

As illustrated in FIGS. 3A and 3B (FIG. 3B is an enlarged view of area AR1 in FIG. 3A), carrier tape 27 includes base tape 27B and cover tape 27C affixed to an upper surface of base tape 27B. Base tape 27B is provided with a plurality of pockets 27P arranged in a line in the longitudinal direction at regular intervals, and each of pockets 27P stores one component BH.

Component BH in each of pockets 27P is prevented from falling off from each of pockets 27P by affixing cover tape 27C to base tape 27B. That is, carrier tape 27 has a configuration in which component BH is sealed in each of the plurality of pockets 27P formed at regular intervals. In addition, a row of feed holes 27K with which an outer peripheral pin of sprocket 26S of component supply unit 26 is engaged is provided in parallel to the row of pockets 27P in base tape 27B as illustrated in FIG. 3B.

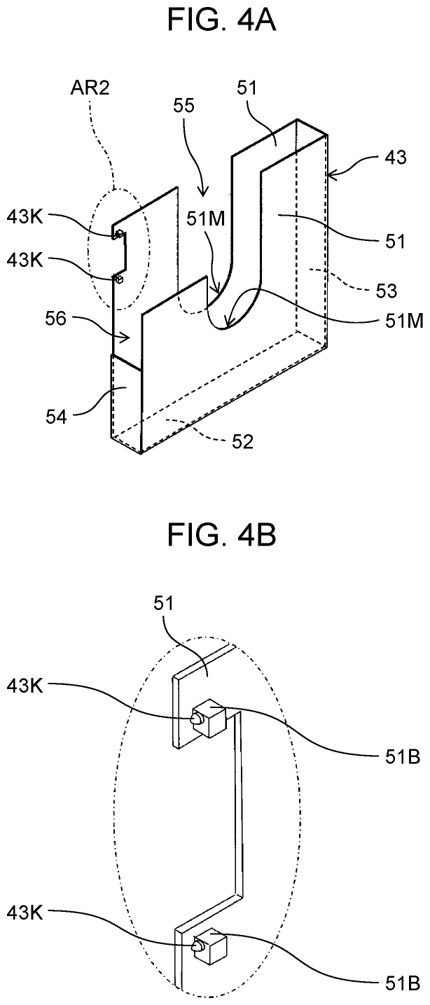

FIG. 4A illustrates case 43 of encased carrier tape roll body 41 in which carrier tape roll body 42 is housed. Case 43 includes left and right side walls 51, bottom wall 52, front wall 53, and rear wall 54, and has a configuration including upper opening 55 and rear opening 56 (that is, a configuration that is open on at least one side).

As can be seen from FIG. 4B (an enlarged view of an area AR2 in FIG. 4A), two upper and lower protruding bases 51B protruding inward from an inner surface of one side wall 51 are provided in an upper part of rear wall 54. Two protruding bases 51B are respectively provided with tape end holders 43K protruding outward in the horizontal direction. Left and right side walls 51 of case 43 are provided with grooves 51M extending in U shapes from edges on upper opening 55 side toward the central parts of side walls 51, respectively.

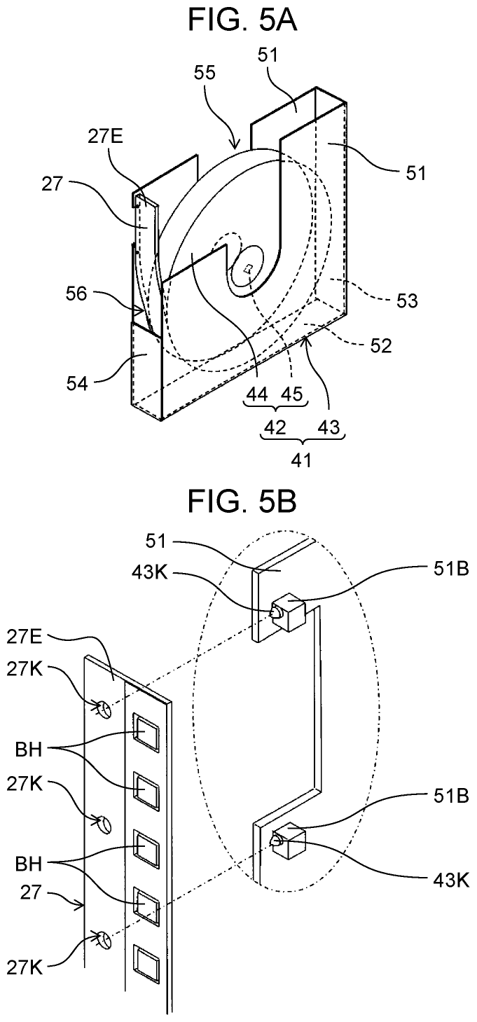

FIG. 5A illustrates carrier tape roll body 42 housed in case 43. When carrier tape roll body 42 is housed in case 43 and carrier tape 27 is not used by being drawn from case 43 (when encased carrier tape roll body 41 is in the state of being stored or transported), feed hole 27K of carrier tape 27 is inserted into and locked to tape end holder 43K provided in case 43 as illustrated in FIG. 5B. In the present exemplary embodiment, two feed holes 27K are respectively inserted into and locked to two tape end holders 43K provided in case 43. This prevents carrier tape 27 from coming off from case 43 of encased carrier tape roll body 41 in the state of being stored or transported so that entire carrier tape roll body 42 is prevented from falling off from case 43.

On the other hand, when carrier tape 27 is drawn from the state of FIG. 5A and used, feed holes 27K of carrier tape 27 are detached from two tape end holders 43K, and then, an attitude is formed such that front wall 53 becomes a lower surface as illustrated in FIG. 3A. When carrier tape 27 is drawn from rear opening 56 in such an attitude with front wall 53 as the lower surface, carrier tape 27 can be fed to component supply unit 26

Since tape end holders 43K are provided in case 43 in this manner in the present exemplary embodiment, a position of an end part of carrier tape 27 in case 43 (an end part on an outer peripheral side of carrier tape roll body 42) is unified, and work of taking out the end part of carrier tape 27 from case 43 can be easily performed. In addition, it is possible to easily cope with a case where the work of taking out the end part of carrier tape 27 is performed by automated equipment such as a robot.

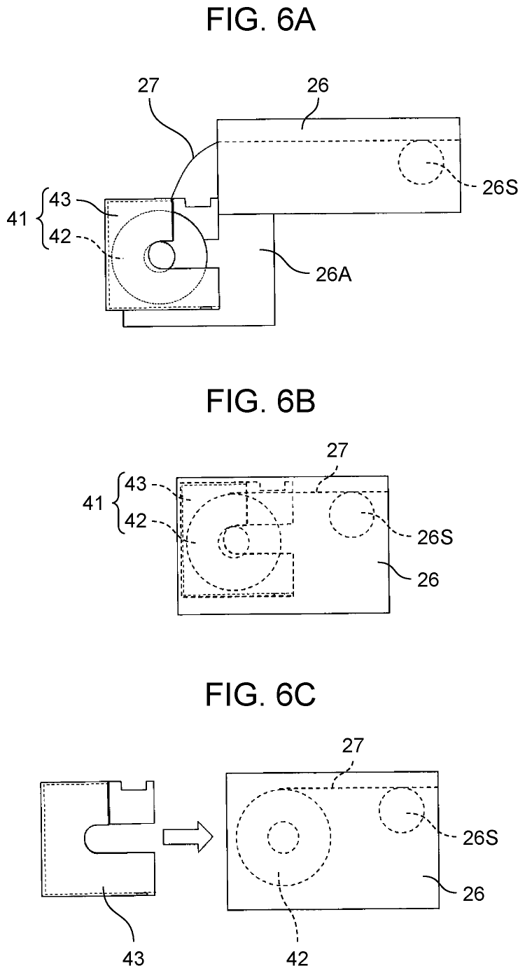

Examples of a usage mode of encased carrier tape roll body 41 with respect to component supply unit 26 include not only a mode of being attached to feeder carriage 25 as in encased carrier tape roll body 41 illustrated on the left side of FIG. 2 but also a mode of being attached to component supply unit 26 through attachment 26A as in encased carrier tape roll body 41 illustrated on the right side of FIG. 2 and FIG. 6A. Alternatively, there is also a mode in which entire encased carrier tape roll body 41 is housed inside component supply unit 26 as illustrated in FIG. 6B. Alternatively, there is also a mode in which carrier tape roll body 42 is extracted from case 43 of encased carrier tape roll body 41, and only such extracted carrier tape roll body 42 is housed inside component supply unit 26 as illustrated in FIG. 6C.

In this manner, in the present exemplary embodiment, case 43 of encased carrier tape roll body 41 can be imparted with a role of a support means for carrier tape roll body 42 when carrier tape roll body 42 is installed outside component supply unit 26 and used.

Next, carrier tape roll body manufacturing device 3 will be described. Carrier tape roll body manufacturing device 3 is a device that manufactures carrier tape roll body 42 by providing memory 45 at an end part of supplied carrier tape 27 (the end part on the center side of roll body 44 when carrier tape 27 is wound in the roll shape), and winding carrier tape 27 from the end part side where memory 45 is provided.

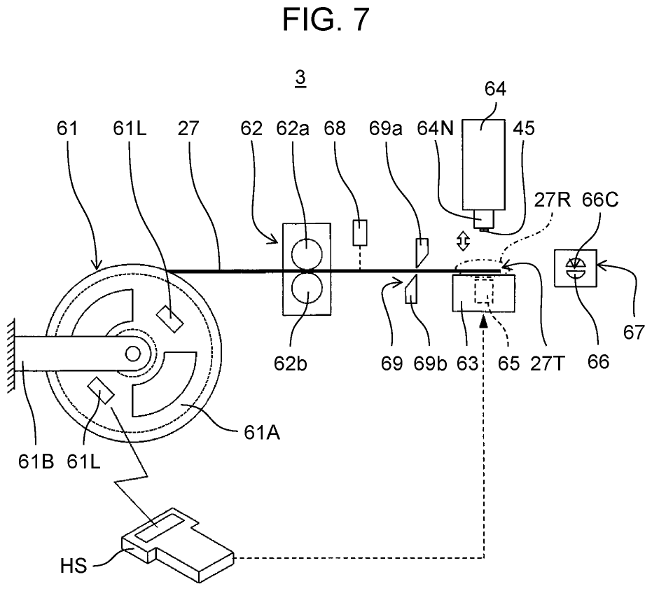

FIG. 7 schematically illustrates a configuration of carrier tape roll body manufacturing device 3. As illustrated in FIG. 7, carrier tape roll body manufacturing device 3 includes tape supply part 61, tape drawing unit 62, backup stage 63, memory installation unit 64, information writing unit 65, rotation shaft 66, rotation shaft driver 67, detector 68, and cutting unit 69.

Tape supply part 61 includes tape supply reel 61A around which carrier tape 27 is wound, and reel support part 61B that rotatably supports tape supply reel 61A. A brake is incorporated inside tape supply reel 61A, and when wound carrier tape 27 is pulled, tape supply reel 61A rotates according to the pulling to feed out carrier tape 27, and the brake is activated to stop the rotation when the pulling of carrier tape 27 is interrupted.

In FIG. 7, code label 61L is affixed to a side surface of tape supply reel 61A.

Various types of information (component information) related to components of carrier tape 27 wound around tape supply reel 61A are recorded in code label 61L. In the present exemplary embodiment, the component information can be read by scanning code label 61L affixed to tape supply reel 61A described above using handy scanner HS as a contactless information reading unit as illustrated in FIG. 7. In this manner, handy scanner HS is a component information acquisition means for acquiring the component information that is information on the component sealed in carrier tape 27 in the present exemplary embodiment.

Carrier tape 27 is wound around tape supply reel 61A in a direction opposite to that of a general component supply reel (hereinafter, referred to as a typical reel). In the typical reel, carrier tape 27 fed out from the reel can be set in component supply unit 26 as it is, and the row of feed holes 27K appears on the right side if carrier tape 27 is drawn to the front from the typical reel in the case of a carrier tape that is a paper tape having a width of 8 mm. On the other hand, in carrier tape 27 drawn to the front from tape supply reel 61A, the row of feed holes 27K appears on the left side opposite thereto. The reason for winding carrier tape 27 around tape supply reel 61A in the opposite direction is to set the orientation of carrier tape 27 of roll body 44 manufactured by carrier tape roll body manufacturing device 3 to be the same as the orientation of the typical reel.

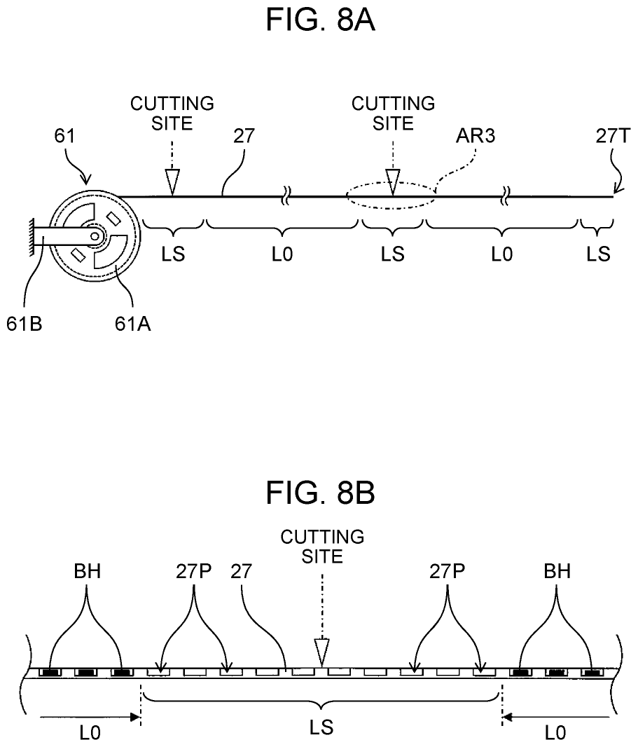

FIG. 8A illustrates a state where a certain amount of carrier tape 27 wound around tape supply reel 61A is drawn. As illustrated in FIG. 8A, an area (referred to as “component-containing pocket area L0”) in which pockets 27P that house components BH, respectively, are continuous and an area (referred to as “empty pocket area LS”) in which pockets 27P that do not house components BH, respectively, are continuous are alternately present on carrier tape 27 wound around tape supply part 61. As illustrated in FIG. 8B (an enlarged view of area AR3 in FIG. 8A), empty pocket area LS includes a plurality of empty pockets 27P.

In FIG. 7, tape drawing unit 62 includes a pair of drawing rollers 62a, 62b, and carrier tape 27 supplied from tape supply part 61 is sandwiched between the pair of drawing rollers 62a, 62b. When tape drawing unit 62 rotates drawing rollers 62a, 62b, carrier tape 27 is pulled by rollers 62a, 62b and drawn from tape supply reel 61A.

In FIG. 7, backup stage 63 is provided on the downstream side of tape drawing unit 62 in a flow of carrier tape 27. Tape drawing unit 62 temporarily stops the drawing of carrier tape 27 in a state where a certain area (hereinafter, referred to as “tip part 27R”) including tip 27T of carrier tape 27 drawn from tape supply part 61 is located above backup stage 63. As a result, a state is formed in which empty pocket area LS in tip part 27R of carrier tape 27 is supported on an upper surface of backup stage 63 (FIG. 7).

In FIG. 7, memory installation unit 64 is provided above backup stage 63. Memory installation unit 64 includes nozzle 64N that can be raised and lowered. Memory 45 can be held at a lower end of nozzle 64N. Nozzle 64N holds memory 45 supplied by a memory supply part (not illustrated).

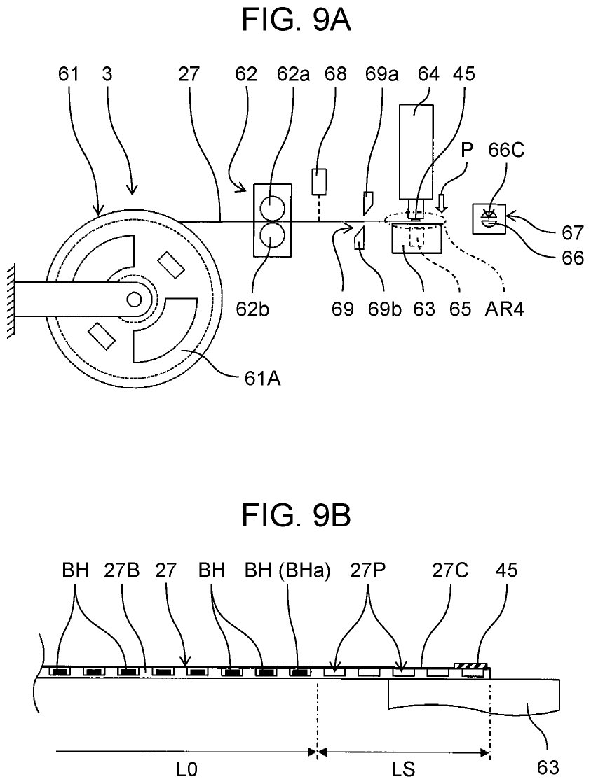

In the present exemplary embodiment, memory 45 is configured using a radio tag whose lower surface is a sticky surface. Memory installation unit 64 lowers nozzle 64N from above tip part 27R of carrier tape 27 supported by backup stage 63 in the state of holding memory 45 at the lower end of nozzle 64N. As a result, memory 45 is pressed against (arrow P illustrated in FIG. 9A) and affixed to the surface of cover tape 27C covering empty pocket area LS inside tip part 27R of carrier tape 27. FIG. 9B (an enlarged view of area AR4 in FIG. 9A) illustrates a state where memory 45 is provided (affixed) to tip part 27R of carrier tape 27.

Here, a position on carrier tape 27 where memory installation unit 64 provides memory 45 is a position closer to tip 27T of carrier tape 27 than component BH (referred to as a “most-distal-side component BHa”, FIG. 9(B)) sealed at a position closest to tip 27T of carrier tape 27. Component BH on the most distal side becomes a component sealed at a position closest to the end part on the center side of roll body 44 when carrier tape 27 is wound in the roll shape to form roll body 44, and becomes component BH to be finally extracted from carrier tape roll body 42 when roll body 44 (carrier tape roll body 42) has been supplied to component mounting device 14. Since memory 45 is provided at the position closer to tip 27T of carrier tape 27 than component BH on the most distal side, memory 45 is present inside carrier tape roll body 42 until carrier tape roll body 42 has no component.

Here, memory 45 is provided with at least one empty pocket 27P between memory 45 and most-distal-side component BHa. As a result, after carrier tape 27 is wound in the roll shape, memory 45 has at least one empty pocket 27P provided between memory 45 and component BH (most-distal-side component BHa) sealed at the position closest to the end part (end part corresponding to tip 27T) of carrier tape 27 on the center side of roll body 44 among components BH sealed in carrier tape 27 wound in the roll shape. FIG. 9B illustrates an example in which memory 45 is provided with four empty pockets 27P between memory 45 and most-distal-side component BHa.

In FIG. 7, information writing unit 65 is provided in backup stage 63. Information writing unit 65 has a function of writing information into memory 45 provided on carrier tape 27 by memory installation unit 64.

Information writing unit 65 writes the above-described component information into memory 45. As described above, handy scanner HS reads the component information from code label 61L, and information writing unit 65 writes the component information read by handy scanner HS into memory 45. The component information can also be written into memory 45 in advance. In this case, information writing unit 65 does not need to write the component information into memory 45.

Information writing unit 65 also writes identification information into memory 45. Here, the “identification information” is information (for example, a serial number) used to distinguish component BH sealed in carrier tape 27 on which carrier tape roll body 42 is to be manufactured from component BH sealed in another carrier tape 27 (component BH sealed in carrier tape 27 of another carrier tape roll body 42).

The identification information is generated by identification information generator 104c of management computer 7 to be described later every time memory 45 is provided at tip part 27R of the carrier tape 27 by memory installation unit 64. The identification information is also used as management information for managing case 43. That is, the identification information is used for both the purpose of identifying carrier tape roll body 42 and the purpose of identifying case 43 in the present exemplary embodiment. In this manner, information writing unit 65 has functions of both a component information writing means and an identification information writing means in the present exemplary embodiment.

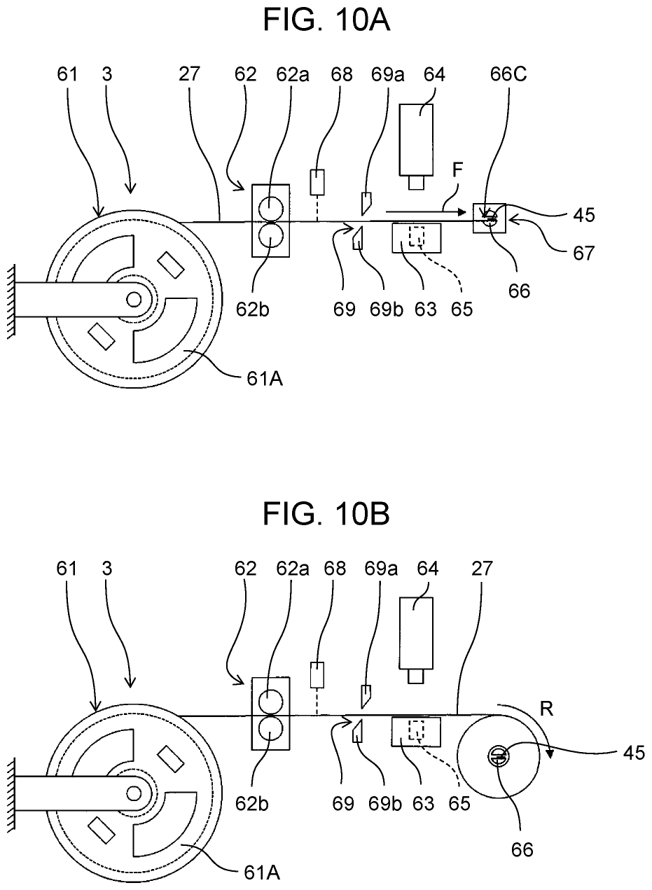

In FIG. 7, rotation shaft 66 is provided on the downstream side of backup stage 63 in the flow of carrier tape 27. Rotation shaft 66 is formed using a shaft-shaped member extending in the horizontal direction. A part of rotation shaft 66 is chuck mechanism 66C that chucks tip part 27R of carrier tape 27 to be supplied from tape supply part 61. When carrier tape 27 having memory 45 in which information has been written by information writing unit 65 is sent toward rotation shaft 66 by tape drawing unit 62 (arrow F illustrated in FIG. 10A), tip part 27R of carrier tape 27 is chucked by chuck mechanism 66C, and carrier tape 27 is attached to rotation shaft 66 (FIG. 10A).

Rotation shaft driver 67 has a function of rotating rotation shaft 66. When rotation shaft driver 67 rotates rotation shaft 66 in a state where tip part 27R of carrier tape 27 is attached to rotation shaft 66 by chuck mechanism 66C (arrow R illustrated in FIG. 10B), carrier tape 27 is wound around rotation shaft 66.

In FIG. 7, detector 68 is provided between tape drawing unit 62 and memory installation unit 64. Detector 68 sets a position immediately below detector 68 as an inspection position, and detects component BH in each of pockets 27P of carrier tape 27 passing through the inspection position according to the rotation of rotation shaft 66. When detector 68 does not continuously detect component BH for a certain period of time in a situation where carrier tape 27 is drawn from tape supply reel 61A by tape drawing unit 62, it can be determined that a head part of empty pocket area LS has reached the inspection position.

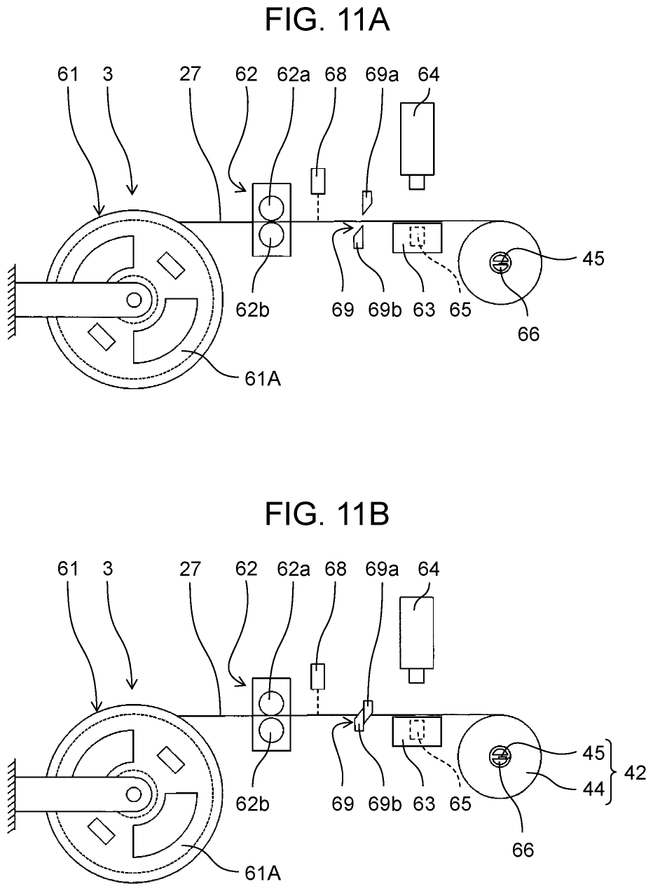

Cutting unit 69 includes a pair of cutter members 69a, 69b. The pair of cutter members 69a, 69b is disposed at positions sandwiching carrier tape 27. When cutting unit 69 activates cutter members 69a, 69b to approach each other (FIG. 11A→FIG. 11B), carrier tape 27 is cut.

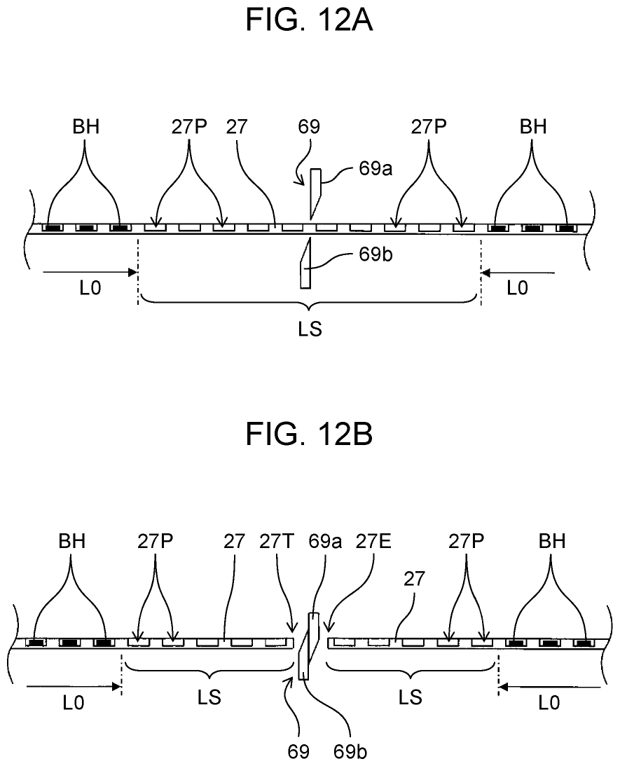

Cutting unit 69 cuts carrier tape 27 with an intermediate part of empty pocket area LS of carrier tape 27 as a cutting site (FIG. 12A→FIG. 12B). Specifically, after detector 68 determines that the head part of empty pocket area LS has reached the inspection position, cutting unit 69 activates cutter members 69a, 69b at a timing when the intermediate part of empty pocket area LS reaches a position (cutting position) where cutter members 69a, 69b face each other.

When cutting unit 69 cuts the cutting site of carrier tape 27 at the cutting position, carrier tape 27 is separated into a side of rotation shaft 66 and a side of tape supply part 61 (FIG. 12B). That is, carrier tape 27 is divided into carrier tape 27 on the side of rotation shaft 66 (a part on the right side in FIG. 12B) and carrier tape 27 on the side of tape supply part 61 (a part on the left side in FIG. 12B).

In addition, when carrier tape 27 is cut at the cutting site, empty pocket area LS including the cutting site is divided into two parts. Further, rear end 27E is generated on carrier tape 27 on the side of rotation shaft 66 side, and new tip 27T is generated on carrier tape 27 on the side of tape supply reel 61A. Further, carrier tape roll body 42 including roll body 44 in which carrier tape 27 is wound in the roll shape and memory 45 provided at the end part of carrier tape 27, wound in the roll shape, on the center side of roll body 44 is generated on rotation shaft 66.

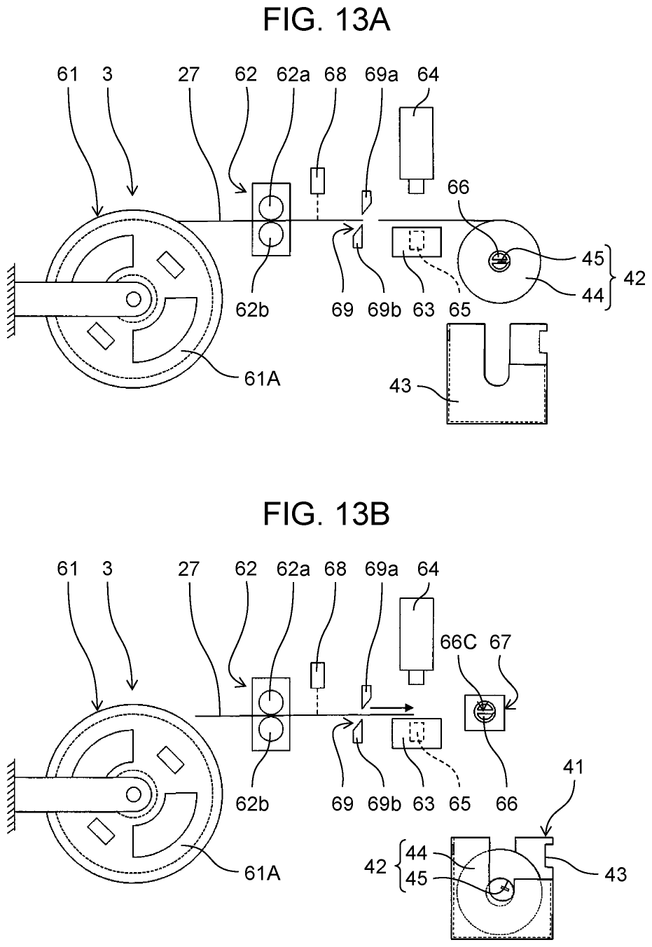

After carrier tape 27 is cut by cutting unit 69, carrier tape roll body manufacturing device 3 moves chuck mechanism 66C by a robot mechanism (not illustrated) or the like to house carrier tape roll body 42 in case 43. In a state where carrier tape roll body 42 is housed in case 43, rotation shaft 66 is located in grooves 51M provided in left and right side walls 51 of case 43. Next, the chuck of carrier tape 27 by rotation shaft 66 is released, and rotation shaft 66 is removed from carrier tape roll body 42. Specifically, when generated carrier tape roll body 42 is moved in the axial direction of rotation shaft 66, carrier tape roll body 42 remains in case 43 and is separated from rotation shaft 66 (FIG. 13A→FIG. 13B). In this manner, encased carrier tape roll body 41 is manufactured.

In this manner, in a method for manufacturing carrier tape roll body 42 by carrier tape roll body manufacturing device 3 according to the present exemplary embodiment, memory 45 is provided at the tip part of the carrier tape supplied from tape supply part 61, tip part 27R of carrier tape 27 is attached to rotation shaft 66, and rotation shaft 66 is rotated. Further, when carrier tape 27 is wound around rotation shaft 66, the carrier tape is cut, and carrier tape 27 wound around rotation shaft 66 is separated from tape supply part 61.

Since memory 45 is provided on carrier tape 27 in carrier tape roll body 42 manufactured as described above, the information on the component is held by carrier tape roll body 42 alone (even without the holding body such as the reel) by writing the information on component BH in memory 45. Thus, carrier tape roll body 42 according to the present exemplary embodiment is easy to use for the operator, and can improve work efficiency.

In addition, memory 45 remains in carrier tape roll body 42 until last component BH (final component) is extracted, and thus, the component information and the identification information regarding carrier tape roll body 42 can be acquired at any time regardless of a consumption state of component BH (even if carrier tape 27 of the used portion is cut on component mounting device 14 side and remaining carrier tape 27 becomes shorter). That is, the information on the components sealed in carrier tape 27 is held regardless of the remaining number of components, and thus, it is possible to grasp the information on components BH sealed in carrier tape 27 throughout the entire use period of carrier tape 27.

Although memory 45 is affixed to the surface of cover tape 27C of carrier tape 27 as an example in which memory 45 is provided on carrier tape 27 in the above description, memory 45 is not necessarily affixed to cover tape 27C. For example, memory 45 may be a chip (formed into a chip shape), and may be housed in any of pockets 27P in empty pocket area LS and sealed together with other components BH. In this case, chip-shaped memory 45 is sealed in a manufacturing process of carrier tape 27.

As described above, when memory 45 is sealed in pocket 27P, it is necessary to prevent memory 45 from being sucked by component suction nozzle 33 of component mounting device 14. Thus, when a terminal part of carrier tape 27 (the end part corresponding to tip 27T of carrier tape 27 described above) comes close, operator OP cuts carrier tape 27 between the final component thereof (component BH sealed at a position closest to tip 27T of carrier tape 27 wound in the roll shape) and memory 45. In the present exemplary embodiment, at least one empty pocket 27P is present between the final component and memory 45 as described above, and thus, the operator can easily find a place where carrier tape 27 is to be cut.

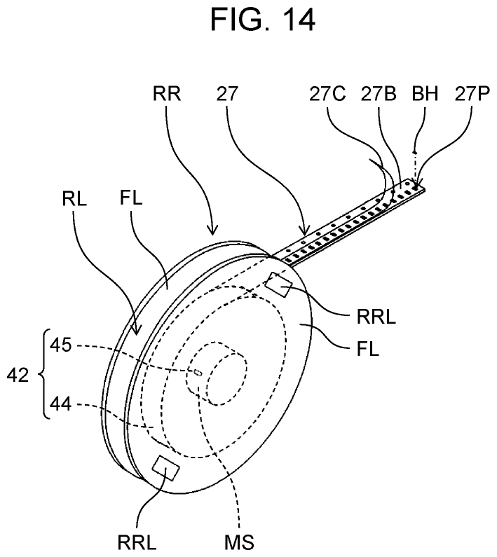

Next, carrier tape roll body handling device 4 will be described. Carrier tape roll body handling device 4 is a device that handles reel-equipped carrier tape roll body RR illustrated in FIG. 14 to manufacture encased carrier tape roll body 41. Reel-equipped carrier tape roll body RR is obtained by holding carrier tape roll body 42 by reel RL, and is manufactured externally (at a place different from component mounting system 1) and brought into component mounting system 1. Reel-equipped carrier tape roll body RR can also be used as a component supply reel that supplies carrier tape 27 to component supply unit 26 of component mounting device 14, but carrier tape roll body 42 is extracted from reel RL by carrier tape roll body handling device 4 and housed in case 43 in a case where the operation is performed such that carrier tape roll body 42 is extracted from reel RL and housed in case 43 thinner than reel RL and carrier tape 27 is supplied to component supply unit 26 in a reel-less manner.

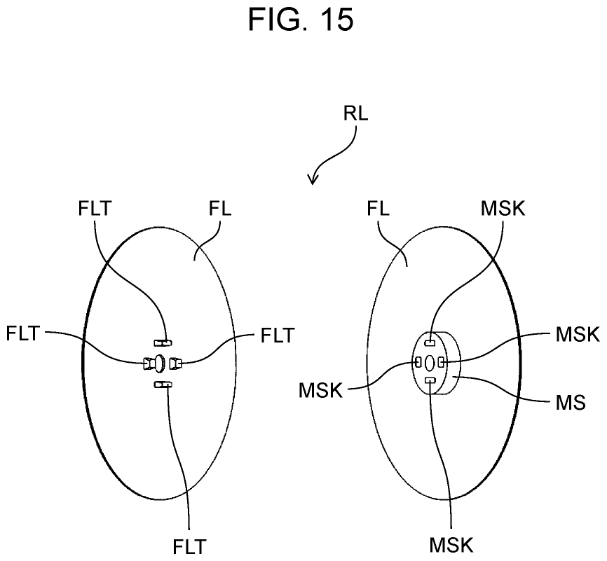

FIG. 15 illustrates a configuration of reel RL. The reel RL includes two side plates FL and winding core MS disposed between two side plates FL, and winding core MS is coupled to one side plate FL. Further, it is configured such that two side plates FL are connected as a plurality of recesses MSK provided on winding core MS of one side plate FL and a plurality of protrusions FLT provided on a side of the other side plate FL are fitted to each other. Thus, when reel RL is disassembled in the present exemplary embodiment, reel RL is divided into two parts, that is, a part including one side plate FL and a part including the other side plate FL.

Reel-equipped carrier tape roll body RR in which carrier tape roll body 42 is held by reel RL can be manufactured by adopting a configuration in which winding core MS is replaced with rotation shaft 66 provided in carrier tape roll body manufacturing device 3 described above. However, information is not written into memory 45 of carrier tape roll body 42 provided in reel-equipped carrier tape roll body RR, and only component information is recorded in identifier RRL affixed to reel RL.

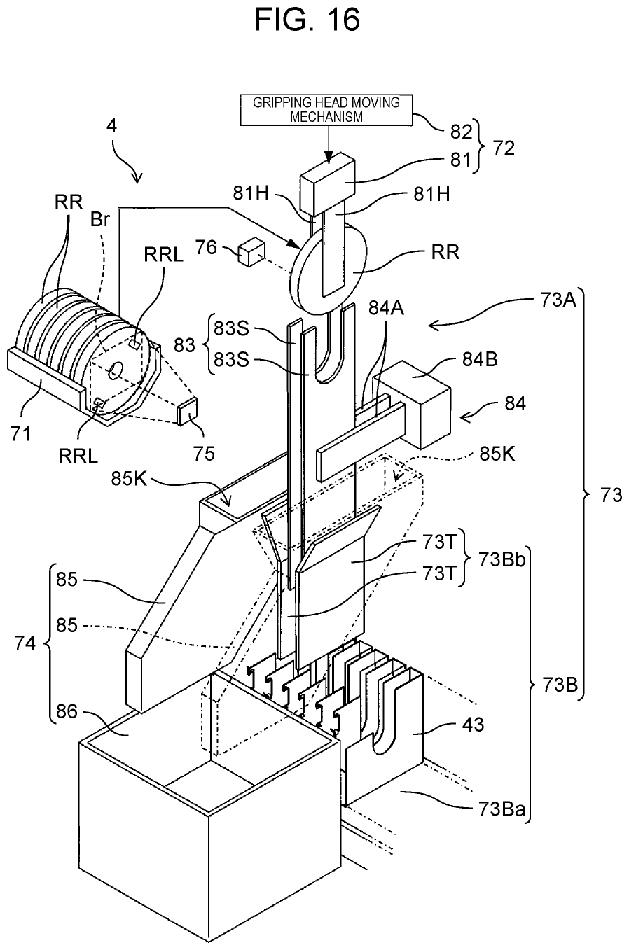

Carrier tape roll body handling device 4 extracts carrier tape roll body 42 from reel RL of reel-equipped carrier tape roll body RR brought from the outside as described above, and operates to collect reel RL while housing carrier tape roll body 42 in case 43. As illustrated in FIGS. 16, 17, and 18, carrier tape roll body handling device 4 includes reel supply part 71, reel conveying unit 72, roll body extractor 73, collector 74, reading unit 75, and writing unit 76.

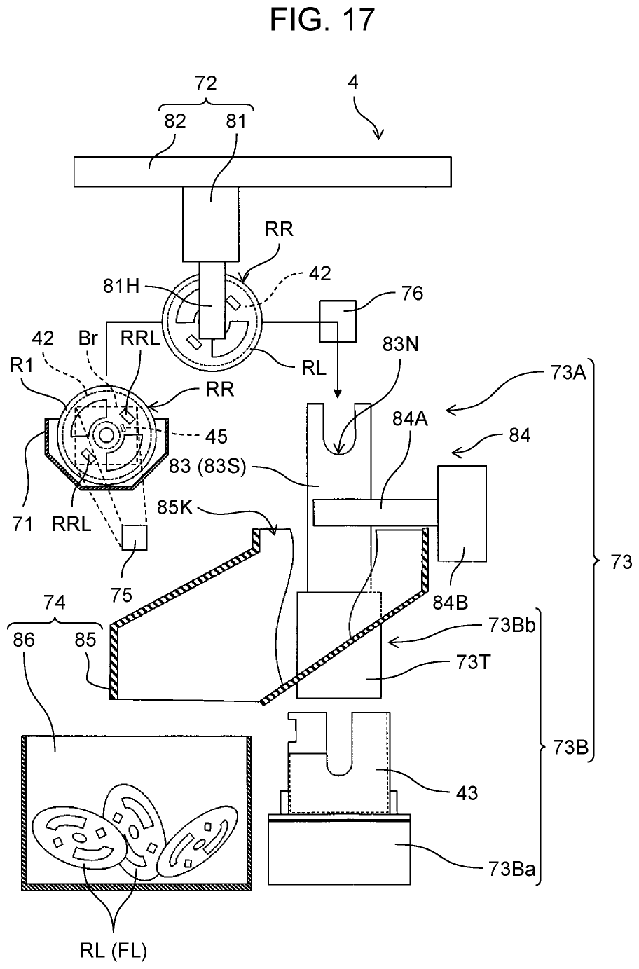

Reel supply part 71 has a function of supplying reel-equipped carrier tape roll body RR. As illustrated in FIGS. 16 and 17, reel supply part 71 is formed using, for example, a container-shaped member that is open upward, and holds a plurality of reel-equipped carrier tape roll bodies RR in the state of being arranged side by side in the lateral direction.

Reel conveying unit 72 has a function of gripping reel-equipped carrier tape roll body RR supplied from reel supply part 71 and moving reel-equipped carrier tape roll body RR above roll body extractor 73. As illustrated in FIGS. 16 and 17, reel conveying unit 72 includes gripping head 81 and gripping head moving mechanism 82. Gripping head 81 grips reel-equipped carrier tape roll body RR supplied by reel supply part 71 by two gripping parts 81H extending downward. Gripping head moving mechanism 82 moves gripping head 81 gripping reel-equipped carrier tape roll body RR in the horizontal plane direction and in the vertical direction.

Roll body extractor 73 has a function of extracting carrier tape roll body 42 from reel RL of reel-equipped carrier tape roll body RR and housing extracted carrier tape roll body 42 in case 43. Roll body extractor 73 includes: separation unit 73A that separates carrier tape roll body 42 from reel RL of reel-equipped carrier tape roll body RR; and roll body housing unit 73B that houses carrier tape roll body 42 separated from reel RL by separation unit 73A in case 43.

Separation unit 73A includes separator 83 and separator driver 84 as illustrated in FIGS. 16 and 17. Separator 83 includes a pair of movable plates 83S facing each other in the horizontal direction and extending in the vertical direction. Each of movable plates 83S is provided with U-shaped clearance 83N recessed downward from an upper edge (FIG. 17).

In FIGS. 16 and 17, separator driver 84 includes a pair of arms 84A and arm driver 84B that moves these two arms 84A. One end parts of the two arms 84A are attached to two movable plates 83S, respectively, and extend in the substantially horizontal direction. Arm driver 84B can change an interval between two arms 84A (hence, interval of separator 83) by moving two arms 84A in the horizontal direction.

In FIGS. 16 and 17, roll body housing unit 73B includes case holder 73Ba and chute 73Bb. Roll body housing unit 73B has a function of holding empty case 43 and conveying empty case 43 in the horizontal direction. Chute 73Bb has a function of guiding carrier tape roll bodies 42 such that carrier tape roll bodies 42 separated from reels RL by separation unit 73A are housed one by one in empty cases 43 held by case holder 73Ba.

As illustrated in FIGS. 16, 17, and 18, case holder 73Ba includes a conveyor mechanism extending in the horizontal direction. The plurality of cases 43 are held in the state of being arranged in a line with upper openings 55 facing upward and are intermittently conveyed in the horizontal direction by case holder 73Ba.

As illustrated in FIGS. 16, 17, and 18, chute 73Bb includes a pair of chute members 73T. Two chute members 73T are disposed to face each other in a direction in which two movable plates 83S constituting separator 83 face each other. Two chute members 73T are disposed below separator 83.

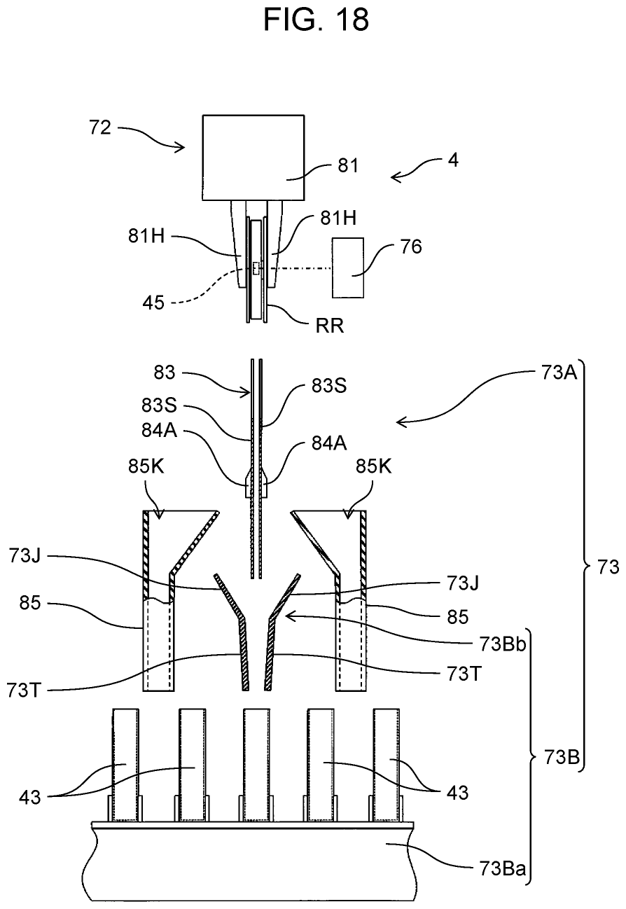

In FIG. 18, two chute members 73T form a shape in which upper end parts 73J are widened as proceeding upward. An interval between upper end parts 73J of two chute members 73T is wider than an interval between lower end parts of two movable plates 83S constituting separator 83. In addition, an interval between two chute members 73T becomes narrower as proceeding toward lower ends (FIG. 18).

Chute 73Bb guides carrier tape roll body 42, separated from reel RL as reel RL is disassembled by separation unit 73A, downward, thereby housing carrier tape roll body 42 in case 43 located on the lower side. As a result, one carrier tape roll body 42 is housed in one case 43.

Collector 74 has a function of collecting reel RL disassembled by separation unit 73A. Collector 74 includes a pair of reel discharge chutes 85 and collection box 86 as illustrated in FIGS. 16 and 17.

Two reel discharge chutes 85 have tubular shapes in which opening parts become wider as proceeding upward. Upper end openings 85K of two reel discharge chutes 85 are located on sides of separator 83 (sides of two movable plates 83S). Collection box 86 is a container-shaped member that is open upward, and is provided below two reel discharge chutes 85.

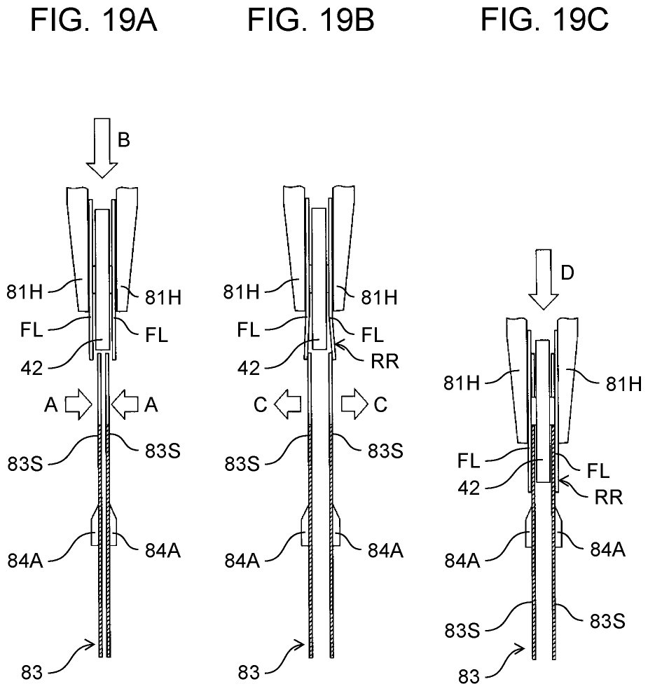

When reel RL is disassembled by separation unit 73A, first, reel-equipped carrier tape roll body RR gripped by gripping head 81 of reel conveying unit 72 is positioned above separator 83 (FIG. 18). Further, the interval between the upper end parts of two movable plates 83S constituting separator 83 is set to be smaller than the interval between two side plates FL constituting reel RL of reel-equipped carrier tape roll body RR (arrow A in FIG. 19A), and then, gripping head 81 is lowered relative to separator 83 such that the upper end parts of two movable plates 83S are inserted between two side plates FL from below (arrow B illustrated in FIG. 19A).

When upper end parts of two movable plates 83S have been inserted between two side plates FL from below, arm driver 84B is activated to increase the interval between two movable plates 83S. At this time, the interval between two movable plates 83S is set to be larger than the interval between two side plates FL (arrow C illustrated in FIG. 19B). As a result, movable plates 83S push and widen side plates FL outward to widen a gap between side plate FL and carrier tape roll body 42.

As the gap between side plate FL and carrier tape roll body 42 is widened by increasing the interval between two movable plates 83S (FIG. 19B), gripping head 81 is further lowered relative to separator 83 (arrow D illustrated in FIG. 19C). As a result, each of two movable plates 83S is inserted into a corresponding one of widened gaps between side plates FL and carrier tape roll body 42. At this time, winding core MS enters clearance 83N formed in each of movable plates 83S.

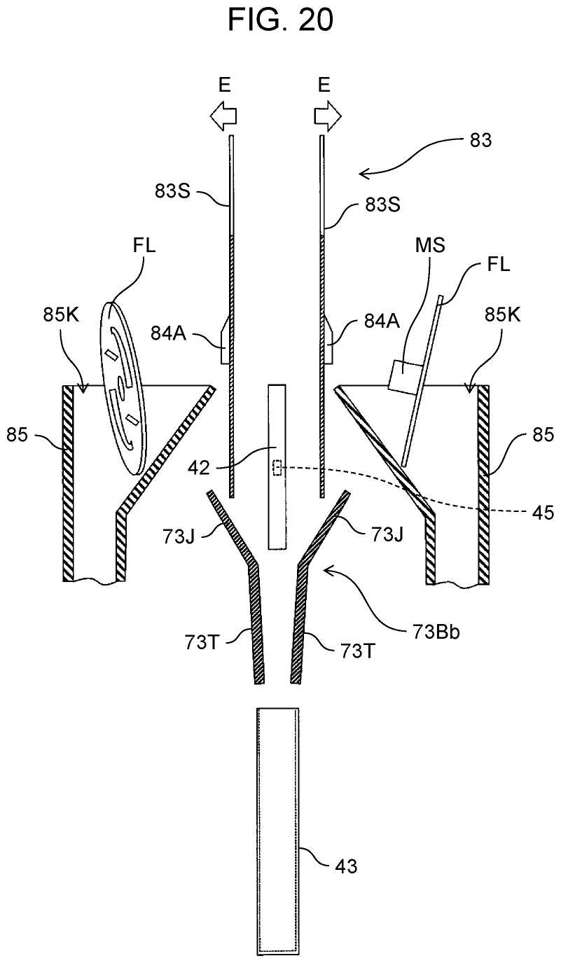

When each of two movable plates 83S is inserted into a corresponding one of the gaps between side plates FL and carrier tape roll body 42, arm driver 84B further widens the interval between two movable plates 83S (arrow E illustrated in FIG. 20). As a result, two side plates FL are pulled off, and the plurality of recesses MSK provided on winding core MS of one side plate FL and the plurality of protrusions FLT provided on the side of the other side plate FL are separated (FIG. 20). As a result, reel RL is divided into two parts, that is, the part including one side plate FL and the part including the other side plate FL, and carrier tape roll body 42 separated from reel RL passes a gap between two chutes 73Bb constituting roll body housing unit 73B and is housed in empty case 43 located immediately below roll body housing unit 73B.

On the other hand, side plate FL on one side of reel RL divided into the two parts drops into upper end opening 85K of reel discharge chute 85 on one side, and side plate FL on the other side drops into upper end opening 85K of reel discharge chute 85 on the other side (FIG. 20). These two side plates FL fall through reel discharge chutes 85, respectively, and enter collection box 86 to be collected.

In FIG. 16, reading unit 75 is provided in the vicinity of reel supply part 71. Reading unit 75 includes a reader or a camera that optically reads information from identifier RRL printed (recorded) on the outer surface of reel RL. Broken line Br in FIGS. 16 and 17 schematically indicates a reading range of reading unit 75.

Identifier RRL includes the component information of component BH housed in carrier tape 27, and reading unit 75 acquires (reads) the component information of component BH housed in carrier tape 27 of reel-equipped carrier tape roll body RR from identifier RRL. Here, the component information also may include at least one of a type of component BH, a component name, characteristics, a date of manufacture, a manufacturer, an expiration date, the number of components, or access information (URL or the like) for accessing these pieces of information.

In this manner, reading unit 75 is a component information acquisition unit that acquires the component information that is the information on the components housed in carrier tape 27 in the present exemplary embodiment. Note that identifier RRL provided on reel RL is a radio tag or the like, a contactless reader having a function of reading information of the radio tag in a contactless manner may be used as reading unit 75. In addition, the component information is read by reading unit 75 from reel RL of reel supply part 71, but may be read from reel RL gripped by gripping head 81.

In addition, reading unit 75 is disposed at a position where the identifier of reel RL of reel supply part 71 can be read in the present exemplary embodiment, but may be disposed at any position as long as the identifier can be read. In addition, reading unit 75 may be mounted on gripping head 81 or a robot arm (not illustrated) so as to be movable. Further, reading unit 75 may be configured using a wireless or wired hand scanner to read the identifier of reel RL by an operation of the operator.

Writing unit 76 writes information into memory 45 provided in carrier tape roll body 42 of reel-equipped carrier tape roll body RR gripped by gripping head 81 by wireless communication. Information to be written in memory 45 by writing unit 76 is component information acquired (read) from identifier RRL affixed to reel RL of reel-equipped carrier tape roll body RR by reading unit 75 and identification information generated (issued) by identification information generator 104c of management computer 7 to be described later. That is, writing unit 76 here has functions of both a component information writing unit and an identification information writing unit. Note that this identification information is also used for both the purpose of identifying carrier tape roll body 42 and the purpose of identifying case 43.

Next, storage warehouse 5 will be described. Storage warehouse 5 stores encased carrier tape roll body 41. Encased carrier tape roll body 41 referred to herein includes not only encased carrier tape roll body 41 that has just been manufactured by carrier tape roll body manufacturing device 3 and handled by carrier tape roll body handling device 4 but also encased carrier tape roll body 41 in use that has been used in component mounting device 14 and returned halfway.

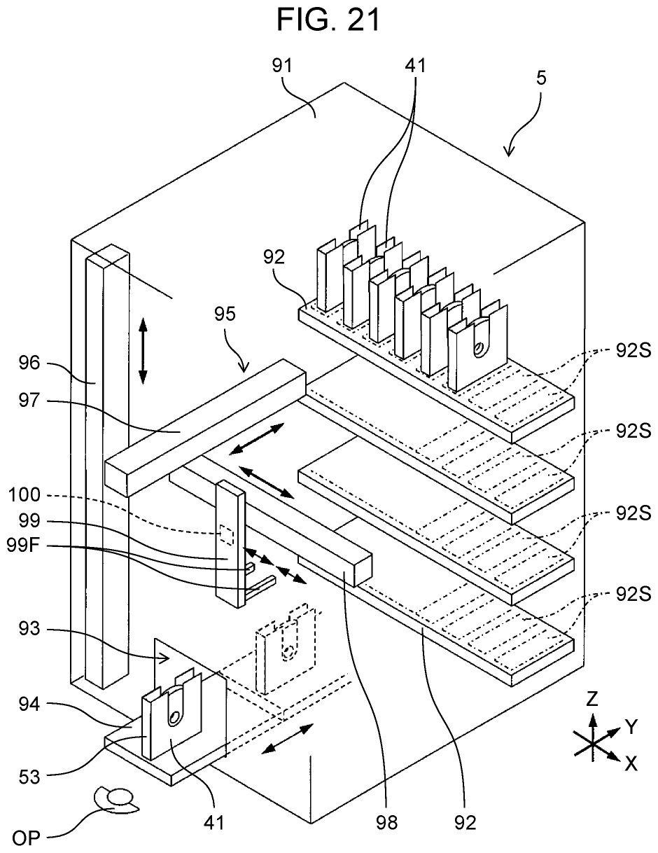

In FIG. 21, storage warehouse 5 includes a plurality of shelves 92 in housing 91. Entrance 93 is provided in a lower part of a front surface of housing 91. Inside housing 91, moving table 94 that performs an operation of protruding to the outside of housing 91 (the front side of operator OP) through entrance 93 and an operation of retracting to the inside of housing 91 (the back side as viewed from operator OP) is provided. Moving table 94 protrudes to the front side of operator OP when encased carrier tape roll body 41 is stored in storage warehouse 5, and retracts to the back side when encased carrier tape roll body 41 placed on moving table 94 is housed in housing 91.

A plurality of storage positions 92S for storing (placing) encased carrier tape roll body 41 is defined in advance in each of the plurality of shelves 92 provided in storage warehouse 5. That is, each of shelves 92 is a storage including the plurality of storage positions 92S for storing cases 43 (that is, encased carrier tape roll body 41) housing carrier tape roll bodies 42 in the present exemplary embodiment.

In FIG. 21, case transfer mechanism 95 (case conveying unit) is provided in housing 91. Case transfer mechanism 95 includes: Z-axis table 96 extending in a vertical direction (referred to as a Z-axis direction); Y-axis table 97 that extends in a front-rear direction (referred to as a Y-axis direction) as viewed from operator OP and is moved in the vertical direction by Z-axis table 96; X-axis table 98 that extends in a lateral direction (referred to as an X-axis direction) as viewed from operator OP and is moved in the front-rear direction by Y-axis table 97; and transfer head 99 that is moved in the X-axis direction by X-axis table 98.

Case transfer mechanism 95 moves transfer head 99 three-dimensionally by a movement operation of Y-axis table 97 in the Z-axis direction by Z-axis table 96, movement of X-axis table 98 in the Y-axis direction by Y-axis table 97, and movement of transfer head 99 in the X-axis direction by X-axis table 98. Transfer head 99 includes two fingers 99F arranged in the X-axis direction.

Two fingers 99F can be close to or away from each other in the X-axis direction. When two fingers 99F are activated to be closed with encased carrier tape roll body 41 located between two fingers 99F, encased carrier tape roll body 41 is gripped by two fingers 99F (that is, by transfer head 99).

In FIG. 21, transfer head 99 is provided with contactless reader 100 in which an imaging visual field is directed in a depth direction as viewed from operator OP. Contactless reader 100 is installed at such a position that enables communication with memory 45 provided in encased carrier tape roll body 41 (reading of information written in memory 45) at a position where transfer head 99 grips encased carrier tape roll body 41.

Contactless reader 100 reads information (component information and identification information) written in memory 45 in the state of being located at the position that enables communication with memory 45. In the present exemplary embodiment, contactless reader 100 functions as an identification information reading unit that reads the identification information written in memory 45. When information written in memory 45 of encased carrier tape roll body 41 is read, contactless reader 100 causes management computer 7 to store the read information (which will be described later).

Unique addresses are respectively given to storage positions 92S defined in each of the plurality of shelves 92. In the present exemplary embodiment, when encased carrier tape roll body 41 is stored (placed) in storage position 92S, information in which the information (component information) of component BH housed in carrier tape roll body 42 (carrier tape 27) of encased carrier tape roll body 41 is associated with (so-called linked with) the identification information of encased carrier tape roll body 41 is stored in management computer 7, and further, information in which the component information is associated with the information on storage position 92S (storage position information) is stored in management computer 7 (which will be described later). As a result, management computer 7 can grasp which storage position 92S of storage warehouse 5 stores encased carrier tape roll body 41 housing which component BH.

Note that case transfer mechanism 95 and shelf 92 disposed inside housing 91 of storage warehouse 5 have been described as examples of the case conveying unit and the storage in the present exemplary embodiment, but these are not limited to those disposed inside housing 91 of storage warehouse 5, and may be disposed in an open space. Furthermore, the case conveying unit may include a conveyance robot that moves on a floor surface or a rail disposed in a factory.

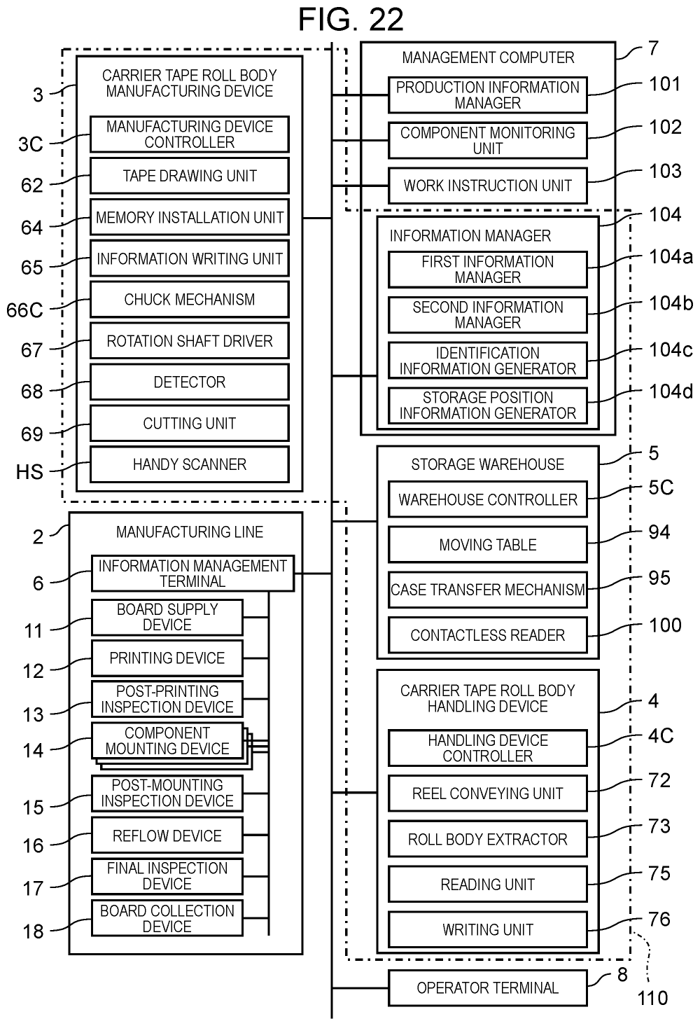

FIG. 22 is a block diagram illustrating a control system in the entire component mounting system 1. As illustrated in FIG. 22, management computer 7 includes production information manager 101, component monitoring unit 102, work instruction unit 103, and information manager 104. Production information manager 101 stores production plan data in component mounting system 1. Component monitoring unit 102 monitors the number of remaining components BH in manufacturing line 2. When a component shortage is predicted, component monitoring unit 102 transmits such a fact to work instruction unit 103.

Work instruction unit 103 gives a work instruction at the time of model switching based on the production plan data stored in production information manager 101 with respect to manufacturing line 2 and operator OP, and gives an instruction for delivery of component BH to be used in production of the next model or the like with respect to storage warehouse 5. In addition, work instruction unit 103 gives work instructions (specifically, an instruction for delivery of a component for replenishment with respect to storage warehouse 5 and an instruction for component replenishment work with respect to operator OP) based on information from component monitoring unit 102.

Information manager 104 includes first information manager 104a, second information manager 104b, identification information generator 104c, and storage position information generator 104d (FIG. 22). First information manager 104a manages the component information, and second information manager 104b manages the information (storage position information) of storage position 92S of component BH in storage warehouse 5.

Specifically, first information manager 104a stores the component information and the identification information on carrier tape roll body 42 manufactured by carrier tape roll body manufacturing device 3 in association with each other. In addition, first information manager 104a stores the component information and the identification information on carrier tape roll body 42 separated from reel RL in carrier tape roll body handling device 4 in association with each other. In the present exemplary embodiment, first information manager 104a is a first information storage unit that stores the component information and the identification information in association with each other.

Second information manager 104b stores the identification information on carrier tape roll body 42 manufactured by carrier tape roll body manufacturing device 3 and the information on storage position 92S (storage position information) in association with each other. In addition, second information manager 104b stores the identification information on carrier tape roll body 42 separated from reel RL in carrier tape roll body handling device 4 and the information on storage position 92S (storage position information) in association with each other. In the present exemplary embodiment, second information manager 104b is a second information storage unit that stores the identification information and the storage position information in association with each other. In addition, information manager 104 is an information storage unit having both functions of the first information storage unit and the second information storage unit.

Identification information generator 104c generates (issues) the identification information on carrier tape roll body 42 when memory installation unit 64 provides memory 45 on carrier tape 27 in carrier tape roll body manufacturing device 3, for example. In addition, when carrier tape roll body handling device 4 disassembles reel RL of reel-equipped carrier tape roll body RR and carrier tape roll body 42 is separated from reel RL, for example, identification information generator 104c generates (issues) the identification information on carrier tape roll body 42. When encased carrier tape roll body 41 is stored in storage warehouse 5, storage position information generator 104d specifies storage position 92S of encased carrier tape roll body 41 to generate the storage position information.

As illustrated in FIG. 22, carrier tape roll body manufacturing device 3 includes manufacturing device controller 3C. Manufacturing device controller 3C controls tape drawing unit 62, memory installation unit 64, information writing unit 65, chuck mechanism 66C, rotation shaft driver 67, detector 68, cutting unit 69, and the like provided in carrier tape roll body manufacturing device 3. In addition, manufacturing device controller 3C can communicate with handy scanner HS.

As illustrated in FIG. 22, carrier tape roll body handling device 4 includes handling device controller 4C. Handling device controller 4C controls reel conveying unit 72, roll body extractor 73, reading unit 75, writing unit 76, and the like provided in carrier tape roll body handling device 4. In addition, storage warehouse 5 includes warehouse controller 5C as illustrated in FIG. 22. Warehouse controller 5C controls moving table 94, case transfer mechanism 95, and contactless reader 100 provided in storage warehouse 5.

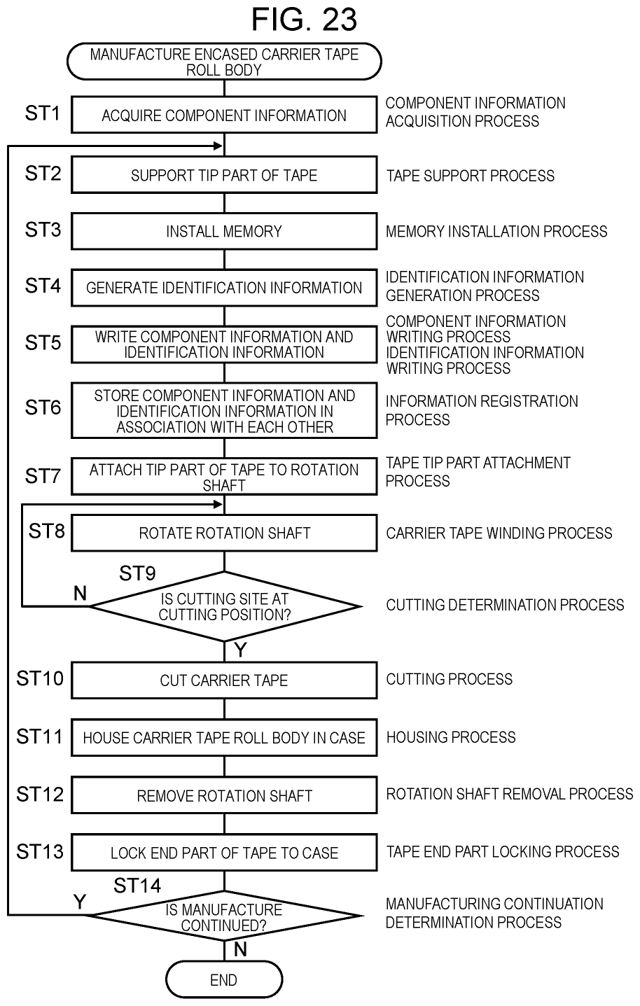

Next, a procedure for performing work of manufacturing carrier tape roll body 42 by carrier tape roll body manufacturing device 3 (the method for manufacturing carrier tape roll body 42) will be described with reference to a flowchart of FIG. 23. In order to manufacture carrier tape roll body 42, first, component information of component BH housed in carrier tape 27 supplied by tape supply part 61 is acquired (a component information acquisition process in step ST1). Specifically, the component information is acquired by scanning code label 61L affixed to tape supply reel 61A with handy scanner HS or the like as described above.

When the component information is acquired in step ST1, tape drawing unit 62 is activated to draw carrier tape 27 from tape supply reel 61A, and tip part 27R of carrier tape 27 is supported by backup stage 63 (a tape support process in step ST2. FIG. 7). Further, memory installation unit 64 is activated to provide memory 45 on tip part 27R of carrier tape 27 (a memory installation process in step ST3. FIGS. 9A and 9B).

When memory 45 is provided at tip part 27R of carrier tape 27, manufacturing device controller 3C causes identification information generator 104c of management computer 7 to generate identification information on carrier tape roll body 42 to be manufactured (an identification information generation process in step ST4). Further, when identification information generator 104c is caused to generate the identification information, the component information acquired in step ST1 and the identification information generated in step ST4 are written into memory 45 (a component information writing process and an identification information writing process in step ST5).

When the component information and the identification information have been written into memory 45, manufacturing device controller 3C transmits the information (the component information and the identification information) written in memory 45 to management computer 7, and stores the information (component information and identification information) in first information manager 104a of management computer 7. As a result, for carrier tape roll body 42 to be manufactured, the identification information, which is information unique to carrier tape roll body 42 and the component information, which is information on component BH housed in carrier tape roll body 42, are registered in management computer 7 in association with each other (an information registration process in step ST6).

When the component information and the identification information are stored in first information manager 104a of management computer 7, manufacturing device controller 3C activates tape drawing unit 62 and activates chuck mechanism 66C to attach tip part 27R of carrier tape 27 provided with memory 45 to rotation shaft 66 (a tape tip part attachment process in step ST7. FIG. 10A. Further, when tip part 27R of carrier tape 27 is attached to rotation shaft 66, manufacturing device controller 3C rotates rotation shaft 66 by rotation shaft driver 67 to wind the carrier tape around rotation shaft 66 (a carrier tape winding process in step ST8. FIG. 10B).

When the rotation of rotation shaft 66 by rotation shaft driver 67 starts, manufacturing device controller 3C determines whether or not the intermediate part (cutting site) of empty pocket area LS has reached the cutting position based on a detection situation of component BH obtained by detector 68 (a cutting determination process in step ST9). Further, when it is determined that the cutting site has reached the cutting position, manufacturing device controller 3C activates cutting unit 69 to cut the cutting site of carrier tape 27 (a cutting process in step ST10. FIG. 11A→FIG. 11B).

After carrier tape 27 is cut, manufacturing device controller 3C moves chuck mechanism 66C by the robot mechanism or the like to house carrier tape roll body 42 in case 43 (a housing process in step ST11). Thereafter, rotation shaft 66 is removed from carrier tape 27 wound around rotation shaft 66 in the roll shape (a rotation shaft removal process in step ST12). Further, the end part (rear end 27E) of carrier tape 27 is locked and fixed to tape end holder 43K of case 43 (a tape end part locking process in step ST13). As a result, one encased carrier tape roll body 41 in which carrier tape roll body 42 is housed in case 43 is manufactured.

When one encased carrier tape roll body 41 is manufactured, manufacturing device controller 3C determines whether or not to continuously manufacture encased carrier tape roll body 41 (a manufacturing continuation determination process in step ST14). Further, the process returns to step ST2 when encased carrier tape roll body 41 is continuously manufactured, and a series of the processes is ended when the manufacturing of encased carrier tape roll body 41 is to be ended.

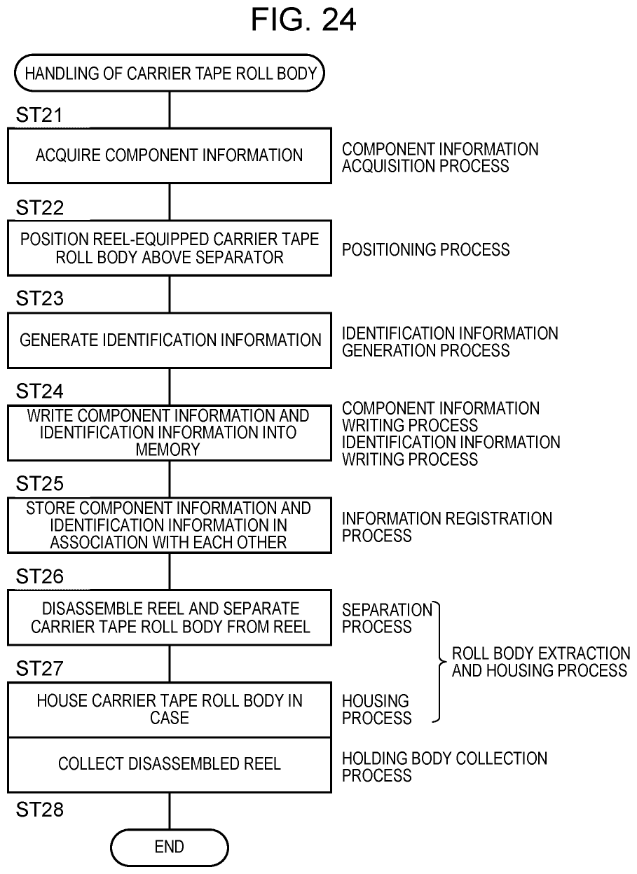

Next, a procedure for performing work of handling carrier tape 27 by carrier tape roll body handling device 4 (a method for handling carrier tape 27) will be described with reference to a flowchart illustrated in FIG. 24. In order to handle carrier tape roll body 42, first, component information of reel-equipped carrier tape roll body RR, set as a work target among reel-equipped carrier tape roll bodies RR supplied by reel supply part 71, is acquired (a component information acquisition process in step ST21). Here, the component information is acquired by reading unit 75 reading information from identifier RRL affixed to reel RL of reel-equipped carrier tape roll body RR as the work target (FIG. 16), but another method may be used. For example, operator OP may perform an input corresponding to a content stored in identifier RRL through an input device (not illustrated) connected to handling device controller 4C.

When the component information of reel-equipped carrier tape roll body RR is acquired in step ST21, handling device controller 4C activates reel conveying unit 72 of carrier tape roll body handling device 4 to cause gripping head 81 to grip reel-equipped carrier tape roll body RR as the work target. Further, when gripping head 81 grips reel-equipped carrier tape roll body RR, gripping head 81 is moved (FIG. 17), and reel-equipped carrier tape roll body RR is positioned above separator 83 (a positioning process in step ST22. FIG. 18).

When reel-equipped carrier tape roll body RR is positioned above separator 83, handling device controller 4C requests identification information generator 104c of management computer 7 to generate identification information on carrier tape roll body 42 separated from reel RL. Further, identification information generator 104c requested by handling device controller 4C to generate identification information generates the identification information on carrier tape roll body 42 extracted by separation of reel RL (an identification information generation process in step ST23).

When the identification information is generated by identification information generator 104c in step ST23, handling device controller 4C of carrier tape roll body handling device 4 receives the generated identification information. Further, writing unit 76 writes the component information acquired in step ST21 and the identification information generated in step ST23 into memory 45 attached to carrier tape roll body 42 of reel-equipped carrier tape roll body RR

(a component information writing process and an identification information writing process in step ST24).

When the component information and the identification information have been written into memory 45 attached to reel-equipped carrier tape roll body RR, handling device controller 4C transmits the information (component information and identification information on carrier tape roll body 42 of reel-equipped carrier tape roll body RR) written in memory 45 to management computer 7, and causes first information manager 104a of management computer 7 to store the information (component information and identification information). As a result, for carrier tape roll body 42 that is to be separated from reel RL, the identification information, which is information unique to carrier tape roll body 42 and the component information, which is information on component BH housed in carrier tape roll body 42, are registered in management computer 7 in association with each other (an information registration process in step ST25).

When the information on carrier tape roll body 42 has been written into first information manager 104a of management computer 7, handling device controller 4C causes separator 83 to disassemble reel RL in the above-described manner (FIG. 19A→FIG. 19B→FIG. 19C) to separate carrier tape roll body 42 from reel RL (a separation process in step ST26). As a result, reel RL is divided into two parts, that is, the part including one side plate FL and the part including the other side plate FL, and carrier tape roll body 42 passes through roll body housing unit 73B and is housed in empty case 43 located immediately below roll body housing unit 73B (a housing process in step ST27). In addition, the reel RL divided into the two parts passes through the inside of reel discharge chute 85 and is collected in collection box 86 (a holding body collection process in step ST28).

Here, the separation process in step ST26 and the housing process in step ST27 constitute a roll body extraction and housing process of extracting carrier tape roll body 42 from reel RL, which is the holding body holding carrier tape roll body 42, and housing extracted carrier tape roll body 42 in case 43. In the housing process out of this roll body extraction and housing process, carrier tape roll body 42 separated from reel RL in the separation process is housed one by one in empty case 43. Thus, one carrier tape roll body 42 can be managed in the unit of one case 43.

When reel RL has been disassembled after writing the information on carrier tape roll body 42 into first information manager 104a of management computer 7, handling device controller 4C ends the series of processes of handling work of carrier tape 27.

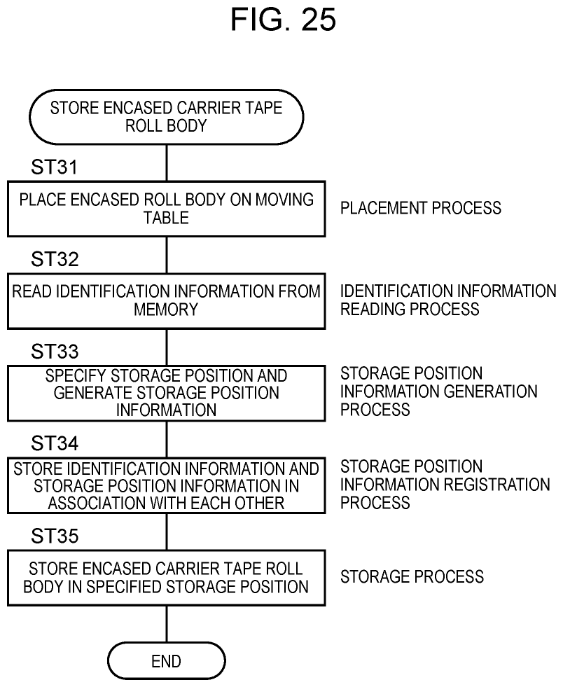

Next, a procedure for performing work of storing encased carrier tape roll body 41 will be described with reference to a flowchart illustrated in FIG. 25. First, warehouse controller 5C of storage warehouse 5 moves moving table 94 to the front side from entrance 93 provided in housing 91. Further, operator OP (or a mobile robot (not illustrated)) places encased carrier tape roll body 41 on moving table 94 (a placement process in step ST31. FIG. 21). At this time, encased carrier tape roll body 41 is placed on moving table 94 in an attitude in which upper opening 55 faces upward and front wall 53 faces the front side (the side of operator OP).

When encased carrier tape roll body 41 has been placed on moving table 94, warehouse controller 5C moves moving table 94 to retract encased carrier tape roll body 41 into housing 91. When encased carrier tape roll body 41 has retracted into housing 91, warehouse controller 5C moves transfer head 99 to the front side of encased carrier tape roll body 41 placed on moving table 94. Further, two fingers 99F are activated to be closed, thereby causing transfer head 99 to grip encased carrier tape roll body 41. At this time, contactless reader 100 provided in transfer head 99 is located at the position that enables the communication with memory 45 provided in carrier tape roll body 42, and contactless reader 100 reads the identification information written in memory 45 (an identification information reading process in step ST32).

When contactless reader 100 reads the identification information written in memory 45, warehouse controller 5C transmits the identification information read by contactless reader 100 to management computer 7. Further, management computer 7 that has received the transmission of the identification information from warehouse controller 5C causes storage position information generator 104d to specify storage position 92S in storage warehouse 5 of encased carrier tape roll body 41 (encased carrier tape roll body 41 whose identification information has been read by contactless reader 100) corresponding to the identification information and generate the storage position information (a storage position information generation process in step ST33). Storage position 92S is specified by being selected from storage positions 92S in empty states at that time arbitrarily or according to a predetermined rule.

When storage position information generator 104d has generated the storage position information in step ST33, management computer 7 causes second information manager 104b to store the generated storage position information in association with the identification information of encased carrier tape roll body 41 corresponding to the storage position information. As a result, for encased carrier tape roll body 41 that is to be stored in storage warehouse 5, the identification information, which is the information unique to carrier tape roll body 42, and the information on the storage position (storage position information) in storage warehouse 5 of encased carrier tape roll body 41 including carrier tape roll body 42 are registered in management computer 7 in association with each other (a storage position information registration process in step ST34).

When the storage information and the identification information on encased carrier tape roll body 41 placed on moving table 94 have been stored in second information manager 104b in association with each other, management computer 7 activates case transfer mechanism 95 to transfer encased carrier tape roll body 41 placed on moving table 94 to storage position 92S corresponding to (specified by) the storage position information for storage (a storage process in step ST35). As a result, the work of storing encased carrier tape roll body 41 ends.

In this manner, carrier tape roll body 42 extracted from reel RL serving as the holding body is housed in case 43 so as to enable the handling as encased carrier tape roll body 41 in the present exemplary embodiment. Encased carrier tape roll body 41 can be made to have a smaller dimension than reel-equipped carrier tape roll body RR in the width direction to achieve downsizing, and also achieves good workability since reel RL does not remain as waste after carrier tape roll body 42 (that is, carrier tape 27) is used up. In addition, case 43 itself is inexpensive, and can be reused (recycled) differently from reel RL, and thus, the cost can be reduced even in this regard.

Furthermore, memory 45 is provided in carrier tape roll body 42, and the component information recorded on tape supply reel 61A or reel RL can be written and stored in memory 45 in the present exemplary embodiment. Thus, even when carrier tape 27 supplied by tape supply part 61 is cut or even when carrier tape roll body 42 is extracted from reel RL, the component information does not become unclear, and the component information can be managed in the unit of one encased carrier tape roll body 41. In addition, the component information and the identification information, which is information unique to carrier tape roll body 42, are stored in association with each other. Thus, even in this regard, it is possible to manage the component information in the unit of one encased carrier tape roll body 41.

In component mounting system 1 described above, carrier tape roll body manufacturing device 3, carrier tape roll body handling device 4, storage warehouse 5, and information manager 104 constitute component management device 110 (FIG. 22).

In work of managing component BH using component management device 110 (a component management method), first, component information is acquired (the component information acquisition process in step ST1 or step ST21), identification information is generated (the identification information generation process in step ST4 or step ST23), the component information and the identification information are written into memory 45 provided in carrier tape roll body 42 (the component information writing process and the identification information writing process in step ST5 or the component information writing process and the identification information writing process in step ST24), and then, these written component information and identification information are stored in first information manager 104a in association with each other (the information registration process in steps ST6 and ST25). Further, the identification information written in memory 45 is read by the identification information reading unit (contactless reader 100) (the identification information reading process in step ST32), storage position 92S is specified to generate the storage position information (the storage position information generation process in step ST33), and then, the identification information and the storage position information are stored in second information manager 104b in association with each other (the storage position information registration process in step ST34).

According to such a component management method, the component information and the identification information on encased carrier tape roll body 41 are stored in association with each other, and further, the identification information and the storage position information of encased carrier tape roll body 41 are stored in association with each other. Thus, it is possible to smoothly perform the storage and extraction of encased carrier tape roll body 41 in storage warehouse 5. Thus, it is possible to easily and efficiently stock and take out components BH according to component management device 110 (component management method) in the present exemplary embodiment.

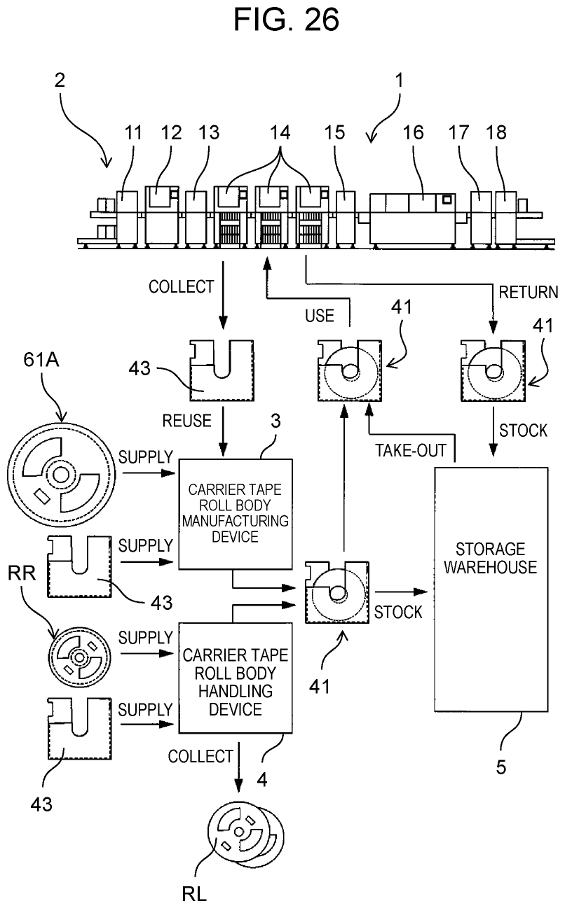

FIG. 26 illustrates an image of the operation of encased carrier tape roll body 41 in component mounting system 1 according to the present exemplary embodiment. As illustrated in this drawing, encased carrier tape roll body 41 in the present exemplary embodiment is manufactured by supplying each of tape supply reel 61A of tape supply part 61 and case 43 to carrier tape roll body manufacturing device 3. Alternatively, encased carrier tape roll body 41 is manufactured by supplying each of reel-equipped carrier tape roll body RR and case 43 to carrier tape roll body handling device 4.

Some of encased carrier tape roll bodies 41 manufactured by carrier tape roll body manufacturing device 3 or encased carrier tape roll bodies 41 manufactured by being handled by carrier tape roll body handling device 4 are fed to manufacturing line 2 and used, and the others are stored (stocked) in storage warehouse 5. Encased carrier tape roll bodies 41 stored in storage warehouse 5 are taken out therefrom and fed to manufacturing line 2 to be used. Further, case 43 generated when carrier tape 27 of encased carrier tape roll body 41 is used up in manufacturing line 2 is collected and supplied to carrier tape roll body manufacturing device 3 or carrier tape roll body handling device 4, and is reused to manufacture new encased carrier tape roll body 41. In addition, some of encased carrier tape roll bodies 41 which have been fed to manufacturing line 2 and in which carrier tapes 27 have not been used up yet are returned to storage warehouse 5 to be stored (stocked).

As described above, component mounting system 1 (the method for handling carrier tape roll body 42) according to the present exemplary embodiment is configured such that carrier tape roll body 42 provided with memory 45 that allows reading and writing by wireless communication on roll body 44 formed by winding carrier tape 27 in the roll shape, is extracted from reel RL serving as the holding body and housed in case 43 (the roll body extraction and housing process constituted by the separation process in step ST26 and the housing process in step ST27). Further, at that time, the identification information to be used to distinguish component BH sealed in carrier tape 27 of carrier tape roll body 42 from a component sealed in another carrier tape is generated (the identification information generation process in step ST23), and is written into memory 45 (the identification information writing process in step ST24).

In addition, the component information is acquired (the component information acquisition process in step ST21), and the acquired component information is written into memory 45 (the component information writing process in step ST24), and further, the acquired component information is stored in information manager 104 of management computer 7, which is the information storage unit, in association with the identification information (the information registration process in step ST25). Since memory 45 is provided on carrier tape 27, the component information is held by carrier tape roll body 42 alone (even without a holding body such as a reel) by writing the information of component BH into memory 45, and a component can be mounted using (reel-less) carrier tape roll body 42 without the holding body such as the reel. Thus, carrier tape roll body 42 according to the present exemplary embodiment is easy to use for the operator, and can improve work efficiency.

In addition, when memory 45 is provided at the end part on the center side of roll body 44 of carrier tape 27 wound in the roll shape, memory 45 remains in carrier tape roll body 42 until the last component BH (final component) is extracted, and thus, the component information and the identification information regarding carrier tape roll body 42 can be acquired at any time regardless of the consumption state of component BH (even if carrier tape 27 of the used portion is cut on component mounting device 14 side and remaining carrier tape 27 becomes shorter). That is, it is possible to grasp the information on components BH sealed in carrier tape 27 throughout the entire use period of carrier tape 27.

Although the exemplary embodiment of the present invention has been described above, the present invention is not limited to the above exemplary embodiment, and various modifications and the like can be made. For example, reel RL of reel-equipped carrier tape roll body RR is divided into two parts in the above-described exemplary embodiment, but this is merely an example, and reel-equipped carrier tape roll body RR may be divided into three or more parts. Even in this case, it suffices that each of a plurality of parts generated by the disassembly passes through reel discharge chute 85 and falls into collection box 86, whereby the disassembled reel RL can be reliably collected.

In addition, the configuration of a disassembly means and a disassembly method of reel RL in carrier tape roll body handling device 4 described in the above exemplary embodiment are merely examples, and dissembling may be performed using other methods to extract carrier tape roll body 42 from reel RL. Furthermore, it is not necessary to disassemble reel RL when a configuration is adopted in which reel RL can be detached without disassembling reel RL (for example, a configuration in which only one side plate FL of reel RL is provided, and winding core MS extends from this one side plate FL in a cantilevered state such that carrier tape roll body 42 can be separated from reel RL by removing carrier tape roll body 42 from winding core MS). Furthermore, the specific configuration of roll body extractor 73 in carrier tape roll body handling device 4 illustrated in the above-described exemplary embodiment is merely an example, and the configuration is arbitrary as long as carrier tape roll body 42 can be extracted from the holding body such as reel RL that holds carrier tape 27 housing component BH in the state of carrier tape roll body 42 and be housed in case 43.

In addition, the specific configuration of carrier tape roll body manufacturing device 3 described in the above-described exemplary embodiment is merely an example, and the configuration is arbitrary as long as it is possible to execute the memory installation process of providing memory 45 at tip part 27R of carrier tape 27 supplied from tape supply part 61, the carrier tape winding process of winding carrier tape 27 around rotation shaft 66 by rotating rotation shaft 66 after attaching tip part 27R of carrier tape 27 on which memory 45 is provided in the memory installation process to rotation shaft 66, and the cutting process of cutting carrier tape 27 supplied from tape supply part 61 to separate carrier tape 27 wound around rotation shaft 66 from tape supply part 61, and further the component information writing process of writing the component information into memory 45 and the identification information writing process of writing the identification information into memory 45. Note that the information is written into memory 45 at the timing before carrier tape 27 is cut in the configuration of carrier tape roll body manufacturing device 3 in the above-described exemplary embodiment, but it may be configured such that the information is written after carrier tape 27 is cut.

In addition, identification information generator 104c that generates (issues) the identification information is provided in management computer 7 in the above-described exemplary embodiment, but identification information generator 104c may be provided in each of carrier tape roll body manufacturing device 3 and carrier tape roll body handling device 4.

According to the present invention, a component can be mounted using information on the component even when the carrier tape roll body is operated without the holding body such as the reel (in the reel-less manner) in the component mounting system.

### INDUSTRIAL APPLICABILITY

The present invention is applicable to a component mounting system that mounts a component on a board and handling of a carrier tape roll body usable in the component mounting system.

### REFERENCE MARKS IN THE DRAWINGS

1 component mounting system
3 carrier tape roll body manufacturing device
27 carrier tape
27P pocket
27C cover tape
27T tip
27R tip part (end part on center side)
41 encased carrier tape roll body
42 carrier tape roll body
43 case
44 roll body
45 memory
61 tape supply part
64 memory installation unit
65 information writing unit (component information writing means) (identification information writing means)
66 rotation shaft
67 rotation shaft driver
69 cutting unit
75 reading unit (component information acquisition unit)
76 writing unit (component information writing unit) (identification information writing unit)
92 shelf (storage)
95 case transfer mechanism (case conveying unit)
104a first information manager (first information storage unit)
104b second information manager (second information storage unit)
104c identification information generator
RR reel-equipped carrier tape roll body
HS handy scanner (component information acquisition means)
RL reel (holding body)
RRL identifier
BH component

1. A component mounting system for performing processing of extracting a carrier tape roll body from a holding body holding the carrier tape roll body and storing the carrier tape roll body in a case,
the carrier tape roll body including
a roll body formed by winding a carrier tape in a roll shape, the carrier tape sealing components respectively in a plurality of pockets formed in the carrier tape at regular intervals, and
a memory that is provided on the carrier tape wound in the roll shape and allows reading and writing by wireless communication, the component mounting system comprising:
an identification information generator configured to generate identification information to be used to distinguish the components sealed in the carrier tape of the carrier tape roll body housed in the case from components sealed in another carrier tape; and
an identification information writing unit configured to write the identification information generated by the identification information generator into the memory.

2. The component mounting system according to claim 1, wherein the memory is provided at an end part of the carrier tape wound in the roll shape, the end part being closer to center of the roll shape.

3. The component mounting system according to claim 1, wherein the identification information writing unit writes the identification information into the memory in a state where the carrier tape roll body is held by the holding body.

4. The component mounting system according to claim 1, further comprising:
a component information acquisition unit configured to acquire component information that is information on the components sealed in the carrier tape; and
a first information storage unit configured to store the component information acquired by the component information acquisition unit in association with the identification information.

5. The component mounting system according to claim 1, further comprising:
a component information acquisition unit configured to acquire component information that is information on the components sealed in the carrier tape; and
a component information writing unit configured to write the component information acquired by the component information acquisition unit into the memory.

6. The component mounting system according to claim 5, wherein the component information is recorded in an identifier provided in the holding body, and the component information acquisition unit reads and acquires the component information from the identifier.

7. The component mounting system according to claim 4, wherein the component information includes at least one of a component type, a component name, a characteristic, a date of manufacture, a manufacturer, an expiration date, a number of the components, and access information for accessing pieces of information on the component type, the component name, the characteristic, the date of manufacture, the manufacturer, the expiration date, and the number of the components.

8. The component mounting system according to claim 1, further comprising:
a storage having a plurality of storage positions for storing the case housing the carrier tape roll body;
a case conveying unit configured to take in and out the case to and from the storage position; and
a second information storage unit configured to store storage position information that allows specification of the storage position in association with the component information stored in the memory of the carrier tape roll body housed at the storage position.

9. A method for performing processing of extracting a carrier tape roll body by which a carrier tape roll body is handled from a holding body holding the carrier tape roll body and storing the carrier tape roll body in a case, the carrier tape roll body including a roll body formed by winding a carrier tape in a roll shape, the carrier tape sealing components respectively in a plurality of pockets formed in the carrier tape at regular intervals, and a memory that is provided on the carrier tape wound in the roll shape and allows reading and writing by wireless communication, the method comprising:
an identification information generation process of generating identification information to be used to distinguish the components sealed in the carrier tape of the carrier tape roll body housed in the case from components sealed in another carrier tape; and
an identification information writing process of writing the identification information generated in the identification information generation process into the memory.

10. The method for handling a carrier tape roll body according to claim 9, wherein the memory is provided at an end part of the carrier tape wound in the roll shape, the end part being closer to center of the roll shape.

11. The method for handling a carrier tape roll body according to claim 9, wherein in the identification information writing process, the identification information is written into the memory in a state where the carrier tape roll body is held by the holding body.

12. The method for handling a carrier tape roll body according to claim 9, further comprising:
a component information acquisition process of acquiring component information that is information on the components sealed in the carrier tape; and
an information registration process of storing the component information acquired in the component information acquisition process in a first information storage unit in association with the identification information.

13. The method for handling a carrier tape roll body according to claim 9, further comprising:
a component information acquisition process of acquiring component information that is information on the components sealed in the carrier tape; and
a component information writing process of writing the component information acquired in the component information acquisition process into the memory.

14. The method for handling a carrier tape roll body according to claim 13, wherein the component information is recorded in an identifier provided in the holding body, and the component information is read and acquired from the identifier in the component information acquisition process.

15. The method for handling a carrier tape roll body according to claim 12, wherein the component information includes at least one of a component type, a component name, a characteristic, a date of manufacture, a manufacturer, an expiration date, a number of the components, and access information for accessing pieces of information on the component type, the component name, the characteristic, the date of manufacture, the manufacturer, the expiration date, and the number of the components.

16. The method for handling a carrier tape roll body according to claim 9, further comprising:
a storage process of storing the case housing the carrier tape roll body at a storage position; and
a storage position information registration process of storing storage position information that allows specification of the storage position in a second information storage unit in association with the component information stored in the memory of the carrier tape roll body housed at the storage position.
